(19) United States
(12) Patent Application Publication
(10) Pub. No.: US 2026/0371856 A1
(43) Pub. Date: Nov. 19, 2026

(54) DISPLAY DEVICE, ELECTRONIC DEVICE HAVING THE DISPLAY DEVICE, AND METHOD OF PROVIDING THE DISPLAY DEVICE

(71) Applicant: Samsung Display Co., LTD., Yongin-si (KR)

(72) Inventors: Young Min MOON, Yongin-si (KR); A Rong KIM, Yongin-si (KR); Jae Ik KIM, Yongin-si (KR); Hee Jun YANG, Yongin-si (KR); Sa Min LEE, Yongin-si (KR)

(21) Appl. No.: 19/444,598

(22) Filed: Jan. 9, 2026

(30) Foreign Application Priority Data
May 13, 2025 (KR) 10-2025-0061812

(51) Int. Cl. H10K 59/122; H10K 59/12; H10K 59/80

(52) U.S. Cl. CPC H10K 59/122; H10K 59/1201; H10K 59/80521; H10K 59/80522

(57) ABSTRACT

A display device includes a substrate including an emission area and a non-emission area, a bank structure on the substrate and defining a tip which faces the non-emission area, an anode contact hole penetrating the bank structure and overlapping the emission area, a light emitting element on the bank structure and including an anode, a light emitting layer and a cathode, an element insulating layer between the bank structure and the anode, and a pixel defining layer on the element insulating layer, covering an edge of the anode, and defining an emission opening overlapping the anode contact hole. A side surface of the pixel defining layer and a side surface of the tip face the non-emission area. The side surface of the pixel defining layer is spaced apart from the side surface of the tip of the bank structure in a direction toward the anode contact hole.

### CROSS REFERENCE TO RELATED APPLICATIONS

This application claims priority to Korean Patent Application No. 10-2025-0061812, filed on May 13, 2025, and all the benefits accruing therefrom under 35 U.S.C. §119, the disclosure of which is incorporated herein in its entirety by reference.

### BACKGROUND

### Field

The present disclosure relates to a display device, an electronic device using the display device, and a method of fabricating the display device.

### 2. Description of the Related Art

As the information society develops, demands for display devices for displaying images are increasing in various forms. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes a light emitting element that enables each pixel of a display panel to emit light by itself. Thus, the light emitting display device can display an image without a backlight unit that provides light to the display panel.

### SUMMARY

With the development of various electronic devices, the demand for high-resolution display devices is increasing. Since high-resolution display devices are required to have high pixel density, a gap between light emitting elements overlapping emission areas, respectively, may be reduced. Therefore, high-resolution display devices may be formed by a patterning process for forming individual pixels rather than a mask process.

An aspect of the present disclosure is to provide a display device capable of providing a high-resolution image, an electronic device using the display device, and a method of fabricating the display device.

Another aspect of the present disclosure is to solve a contact defect of a cathode included in a light emitting element.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

In an embodiment of the disclosure, a display device includes a substrate including an emission area and a non-emission area; a bank structure located on the substrate and including a tip which faces the non-emission area; an anode contact hole penetrating the bank structure and overlapping the emission area; a light emitting element located on the bank structure and including an anode, a light emitting layer and a cathode; an element insulating layer located between the bank structure and the anode; and a pixel defining layer located on the element insulating layer, covering an edge of the anode, and defining an emission opening overlapping the anode contact hole, where a side surface of the pixel defining layer which faces the non-emission area is spaced apart from a side surface of the tip of the bank structure in a direction toward the anode contact hole.

In an embodiment, the bank structure includes a first bank layer; a second bank layer located on the first bank layer; and a third bank layer having a tip which protrudes more than a side surface of the second bank layer toward the non-emission area, where the element insulating layer may cover an upper surface of the third bank layer and a side surface of the first bank layer, a side surface of the second bank layer and a side surface of the third bank layer which face the anode contact hole.

In an embodiment, an anode auxiliary electrode overlapping the anode contact hole and located between the anode and the element insulating layer; and an anode planarization layer located in the anode contact hole and located between the anode and the anode auxiliary electrode, where the anode auxiliary electrode may cover the side surface of the first bank layer, the side surface of the second bank layer and the side surface of the third bank layer which face the anode contact hole, and the anode planarization layer is entirely surrounded by the anode and the anode auxiliary electrode.

In an embodiment, an upper surface of the element insulating layer may include a first portion in contact with the anode auxiliary electrode; and a second portion in contact with the pixel defining layer.

In an embodiment, the upper surface of the element insulating layer may further include a third portion in contact with the light emitting layer, and the second portion is located between the first portion and the third portion.

In an embodiment, the pixel defining layer and the element insulating layer may include staircase-like steps, and the light emitting layer and the cathode include staircase-like steps in a portion overlapping the non-emission area.

In an embodiment, a side surface of the element insulating layer which faces the non-emission area may be located on the same line as the side surface of the tip of the third bank layer.

In an embodiment, the side surface of the element insulating layer which faces the non-emission area may be spaced apart from the side surface of the tip of the third bank layer in the direction toward the anode contact hole.

In an embodiment, the side surface of the pixel defining layer and the side surface of the element insulating layer which face the non-emission area may be located on the same line.

In an embodiment, the third bank layer and the element insulating layer may include staircase-like steps.

In an embodiment, the upper surface of the third bank layer may include a first portion in contact with the element insulating layer and a second portion in contact with the light emitting layer.

In an embodiment, the display device may further include a cathode auxiliary electrode located on the cathode; and an element inorganic layer located on the cathode auxiliary electrode, where the cathode contacts the tip of the third bank layer, the cathode auxiliary electrode contacts the second bank layer, and the element inorganic layer may be spaced apart from the first bank layer in a direction perpendicular to a surface of the substrate.

In an embodiment of the disclosure, a method of fabricating a display device, the method includes forming an anode contact hole which penetrates a bank structure and an element insulating layer; forming an anode planarization layer between an anode auxiliary electrode and an anode; forming a tip of the bank structure and an emission opening after forming a pixel defining layer on the anode; and forming a light emitting layer, a cathode and an element inorganic layer on the anode.

In an embodiment, in the forming of the tip of the bank structure and the emission opening after the forming of the pixel defining layer on the anode, the pixel defining layer may be formed using a photoresist which includes a first portion and a second portion having different thicknesses, and the first portion and the second portion of the photoresist are formed using a halftone mask.

In an embodiment, in the forming of the light emitting layer, the cathode and the element inorganic layer on the anode, the light emitting layer and the cathode may be formed by a photolithography process.

In an embodiment of the disclosure, an electronic device includes at least one display device including a substrate which includes an emission area and a non-emission area; and at least any one of a display module, a processor, a memory, and a power module connected to the at least one display device, where the at least one display device includes a bank structure located on the substrate and including a tip which faces the non-emission area; an anode contact hole penetrating the bank structure and overlapping the emission area; a light emitting element located on the bank structure and including an anode, a light emitting layer and a cathode; an element insulating layer located between the bank structure and the anode; and a pixel defining layer located on the element insulating layer, covering an edge of the anode, and defining an emission opening overlapping the anode contact hole, where a side surface of the pixel defining layer which faces the non-emission area is spaced apart from a side surface of the tip of the bank structure in a direction toward the anode contact hole.

According to a display device according to embodiments, an electronic device using the display device, and a method of fabricating the display device, it is possible to provide a high-resolution image and solve a contact defect of a cathode included in a light emitting element.

However, the effects of the present disclosure are not restricted to the one set forth herein. The above and other effects of the present disclosure will become more apparent to one of daily skill in the art to which the present disclosure pertains by referencing the detailed description of the present disclosure given below.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a cross-sectional view of the display device according to the embodiment;

FIG. 3 is a plan view of a display layer of the display device according to the embodiment;

FIG. 4 is a plan view illustrating the arrangement of a plurality of pixels in a display area of FIG. 3;

FIG. 5 is a cross-sectional view of an example of the display layer taken along line A1-A1’ of FIG. 4;

FIG. 6 is an enlarged cross-sectional view of a display element layer overlapping a first emission area in FIG. 5;

FIG. 7 is an enlarged cross-sectional view of area ‘A’ in FIG. 6;

FIG. 8 is an enlarged cross-sectional view of a display element layer overlapping the first emission area in FIG. 5 according to a comparative example;

FIG. 9 is a cross-sectional view of an example of the display layer taken along line A1-A1’ of FIG. 4;

FIG. 10 is an enlarged cross-sectional view of a display element layer overlapping a first emission area in FIG. 9;

FIG. 11 is an enlarged cross-sectional view of area ‘C’ in FIG. 10;

FIG. 12 is a flowchart illustrating a method of fabricating the display element layer in FIG. 5;

FIGS. 13 through 16 are cross-sectional views illustrating operation S100 of FIG. 12;

FIGS. 17 through 20 are cross-sectional views illustrating operation S200 of FIG. 12;

FIGS. 21 through 26 are cross-sectional views illustrating operation S300 of FIG. 12;

FIGS. 27 through 30 are cross-sectional views illustrating operation S400 of FIG. 12;

FIG. 31 is a block diagram of an electronic device according to an embodiment; and

FIG. 32 is a schematic diagram of electronic devices according to various embodiments.

### DETAILED DESCRIPTION

Advantages and features of the present disclosure and methods of accomplishing the same may be understood more readily by reference to the following detailed description of embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the present disclosure to those skilled in the art, and the present disclosure will only be defined by the appended claims.

It will be understood that when an element or layer is referred to as being related to another element such as being "on” another element or layer, the element or layer can be directly on another element or layer or intervening elements or layers. In contrast, when an element or layer is referred to as being related to another element such as being "directly on” another element or layer, no other element or layer or intervening elements or layers.

Like reference numerals refer to like elements throughout the specification. Shapes, sizes, ratios, angles, numbers, etc. disclosed in the drawings for describing embodiments are merely an example, and the present disclosure is not limited to the illustrated details.

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the present disclosure.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

As being overlapping, elements may be disposed along a same line in a direction, such as along a thickness direction, a lateral direction, etc. For example, one element may be above or below another element along a thickness direction, so as to be be considered overlapping each other, without being limited thereto.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Features of various embodiments of the present disclosure may be partially or entirely coupled to or combined with each other, and may be inter-operated and driven in technically various ways. The embodiments may be implemented independently from each other, or may be implemented together in a co-dependent relationship.

Hereinafter, specific embodiments will be described with reference to the accompanying drawings.

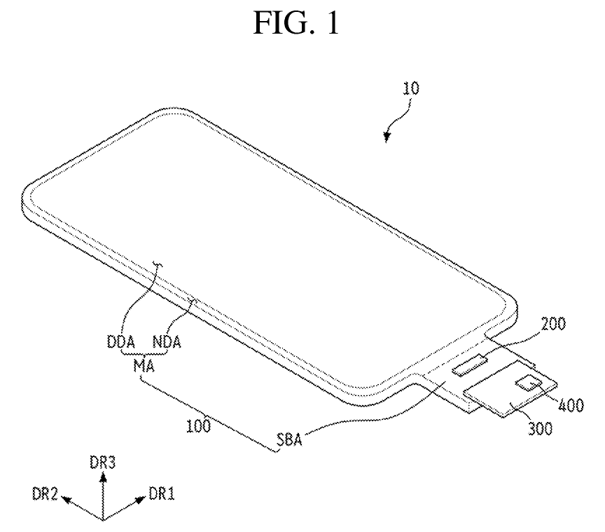

FIG. 1 is a perspective view of a display device 10 according to an embodiment.

Referring to FIG. 1, the display device 10 may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display unit of a television, a notebook computer, a monitor, a billboard, or an Internet of things (IoT) device. For another example, the display device 10 may be applied to wearable devices such as smart watches, watch phones, glasses-type displays, and head mounted displays (HMDs).

The display device 10 may have a planar shape similar to a quadrangle. For example, the display device 10 may have a planar shape similar to a quadrangle having short sides in a first direction DR1 and long sides in a second direction DR2. Each corner where a short side extending in the first direction DR1 meets a long side extending in the second direction DR2 may be rounded to have a selected curvature or may be right-angled. The planar shape of the display device 10 is not limited to a quadrangular shape but may also be similar to other polygonal shapes, a circular shape, or an oval shape.

The display device 10 may include a display panel 100, a display driver 200, a circuit board 300, and a touch driver 400.

The display panel 100 may include a main area MA and a sub-area SBA. The main area MA may include a display area DDA including pixels PX that display an image, and a non-display area NDA located around the display area DDA. The sub-area SBA may be considered a part of the non-display area NDA, without being limited thereto.

The display area DDA may emit light from a plurality of emission areas or a plurality of openings which will be described later. For example, the display panel 100 may include a pixel circuit including switching elements, an element insulating layer defining an emission area or an opening, and a self-light emitting element. For example, the self-light emitting element may include, but is not limited to, at least one of an organic light emitting diode including an organic light emitting layer, a quantum dot light emitting diode including a quantum dot light emitting layer, an inorganic light emitting diode including an inorganic semiconductor, and a micro light emitting diode. The drawings below illustrate a case where the self-light emitting element is an organic light emitting diode.

The non-display area NDA may be an area outside the display area DDA, in the plan view. The non-display area NDA may be defined as an edge area of the main area MA of the display panel 100.

The sub-area SBA may extend from a side of the main area MA. The sub-area SBA may include a flexible material that can be bent, folded, rolled, etc. For example, when the sub-area SBA is bent, it may be overlapped by the main area MA in a thickness direction (e.g., a third direction DR3). The sub-area SBA may include the display driver 200 and a pad unit which is connected to the circuit board 300. In an embodiment, the sub-area SBA may be omitted, and the display driver 200 and the pad unit may be located in the non-display area NDA.

The display driver 200 may output signals and voltages for driving the display panel 100. The display driver 200 may be formed as an integrated circuit and mounted on the display panel 100 by a chip on glass (COG) method, a chip on plastic (COP) method, or an ultrasonic bonding method. For example, the display driver 200 may be located in the sub-area SBA and may be overlapped by the main area MA in the thickness direction by the bending of the sub-area SBA. For another example, the display driver 200 may be mounted on the circuit board 300.

The circuit board 300 may be attached onto the pad unit of the display panel 100 using an anisotropic conductive film (ACF). The circuit board 300 may be a flexible printed circuit board, a printed circuit board, or a flexible film such as a chip on film.

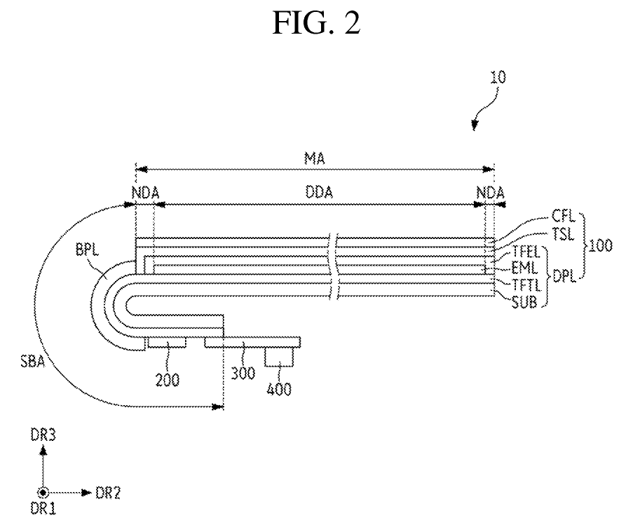

The touch driver 400 may be mounted on the circuit board 300. The touch driver 400 may be connected to a touch sensor layer TSL (see FIG. 2) for sensing and driving a touch.

FIG. 2 is a cross-sectional view of the display device 10 according to the embodiment.

Referring to FIG. 2, the display panel 100 may include a display layer DPL, the touch sensor layer TSL, and a color filter layer CFL. The display layer DPL may include a substrate SUB, a transistor layer TFTL, a display element layer EML, and a thin-film encapsulation layer TFEL.

The substrate SUB may be a base substrate or a base member. The substrate SUB may be a flexible substrate that can be bent, folded, rolled, etc. For example, the substrate SUB may include polymer resin such as polyimide (PI), but the present disclosure is not limited to this example. In an embodiment, the substrate SUB may include a glass material or a metal material.

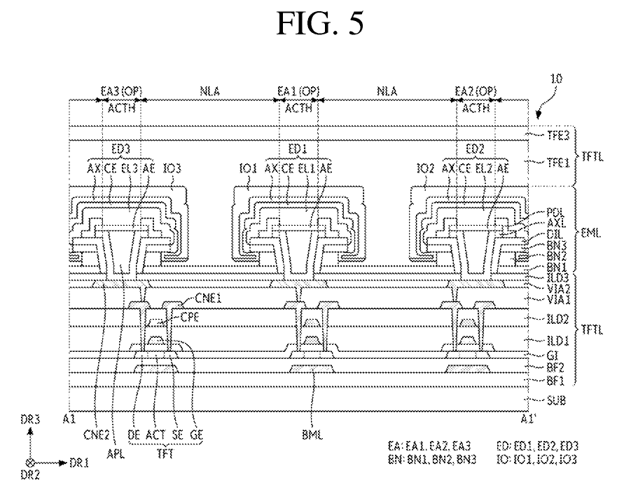

The transistor layer TFTL may be located on the substrate SUB. The transistor layer TFTL may be located in portions overlapping the display area DDA, the non-display area NDA, and the sub-area SBA. The transistor layer TFTL may include a plurality of transistors TFT (see FIG. 5).

The display element layer EML may be located on the transistor layer TFTL. The display element layer EML may be connected (electrically) to the transistor layer TFTL. The display element layer EML may be located in a portion overlapping the display device DDA. The display element layer EML may include, but is not limited to, at least one of an organic light emitting diode including an organic light emitting layer, a quantum dot light emitting diode including a quantum dot light emitting layer, an inorganic light emitting diode including an inorganic semiconductor, and a micro light emitting diode.

The thin-film encapsulation layer TFEL may be located on the display element layer EML. The thin-film encapsulation layer TFEL may be located in portions overlapping the display area DDA and the non-display area NDA. The thin-film encapsulation layer TFEL may cover upper and side surfaces of the display element layer EML and may protect the display element layer EML from external oxygen and moisture. The thin-film encapsulation layer TFEL may include at least one inorganic layer and at least one organic layer to encapsulate the display element layer EML. The thin-film encapsulation layer TFEL can be omitted depending on embodiments.

The touch sensor layer TSL may be located on the thin-film encapsulation layer TFEL. The touch sensor layer TSL may be located in the portions overlapping the display area DDA and the non-display area NDA. The touch sensor layer TSL may sense a user’s touch in a mutual capacitance manner or a self-capacitance manner. The touch sensor layer TSL can be omitted depending on embodiments.

The color filter layer CFL may be located on the touch sensor layer TSL. The color filter layer CFL may be located in the portions overlapping the display area DDA and the non-display area NDA. The color filter layer CFL may absorb a portion of light coming from the outside of the display device 10, thereby reducing reflected light caused by the external light. Therefore, the color filter layer CFL can prevent color distortion caused by reflection of external light.

Since the color filter layer CFL is directly located on the touch sensor layer TSL, the display device 10 may not require a separate substrate for the color filter layer CFL. Therefore, a thickness of the display device 10 may be relatively small. The color filter layer CFL can be omitted depending on embodiments.

As illustrated in FIG. 2, a portion of the display panel 100 which overlaps the sub-area SBA may be bent. When the portion of the display panel 100 is bent, the display driver 200, the circuit board 300, and the touch driver 400 may be overlapped by the main area MA in the third direction DR3.

When the portion of the display panel 100 is bent, a bending protection layer BPL may protect a structure located under the bending protection layer BPL and overlapping the sub-area SBA from bending stress.

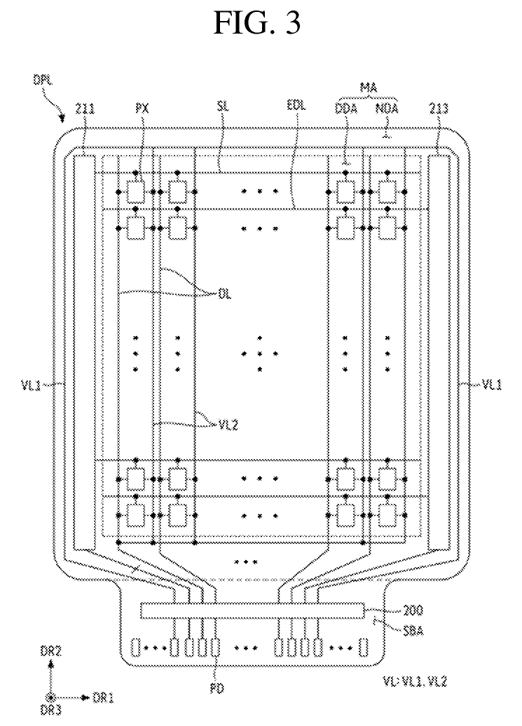

FIG. 3 is a plan view of the display layer DPL of the display device 10 according to the embodiment.

Referring to FIG. 3, the display layer DPL may include a plurality of pixels PX and a plurality of power lines VL, a scan line SL provided in plural including a plurality of scan lines SL, an emission control line EDL provided in plural including a plurality of emission control lines EDL, and a plurality of data lines DL connected to the pixels PX in a portion overlapping the display area DDA. Within the Figures and the text of the disclosure, a reference number indicating a singular form of an element may also be used to reference a plurality of the element.

The scan lines SL may extend in the first direction DR1, and may be spaced apart from each other in the second direction DR2 intersecting the first direction DR1. The scan lines SL may be arranged along the second direction DR2. The scan lines SL may sequentially supply scan signals to the pixels PX.

The emission control lines EDL may extend in the first direction DR1 and may be spaced apart from each other in the second direction DR2. The emission control lines EDL may be arranged along the second direction DR2. The emission control lines EDL may sequentially supply emission signals to the pixels PX.

The data lines DL may extend in the second direction DR2 and may be spaced apart from each other in the first direction DR1. The data lines DL may be arranged along the first direction DR1. The data lines DL may supply data voltages to the pixels PX. The data voltages may determine luminances of the pixels PX.

The power lines VL may include a main power line VL1 and sub-power lines VL2. At least any one of a first power voltage (a high potential voltage) and a second power voltage (a low potential voltage) may be transmitted to the sub-power lines VL2 through the main power line VL1 overlapping the non-display area NDA. The main power line VL1 and the sub-power lines VL2 may be collectively referred to as the power lines VL.

The non-display area NDA may surround the display area DDA. The non-display area NDA may include a scan driver 211 and an emission control driver 213.

The scan driver 211 may be located outside one side of the display area DDA or on one side of the non-display area NDA. The scan driver 211 may include a plurality of driving transistors which generate gate signals based on a gate control signal.

The emission control driver 213 may be located outside the other side of the display area DDA or on the other side of the non-display area NDA. The emission control driver 213 may include a plurality of emission control transistors which generate emission signals based on an emission control signal.

The display layer DPL included in an embodiment may include the display driver 200, and a pad provided in plural including a plurality of pad electrodes PD in a portion overlapping the sub-area SBA. The pad electrodes PD may be spaced apart from each other in the first direction DR1 and may be connected to different lines, respectively.

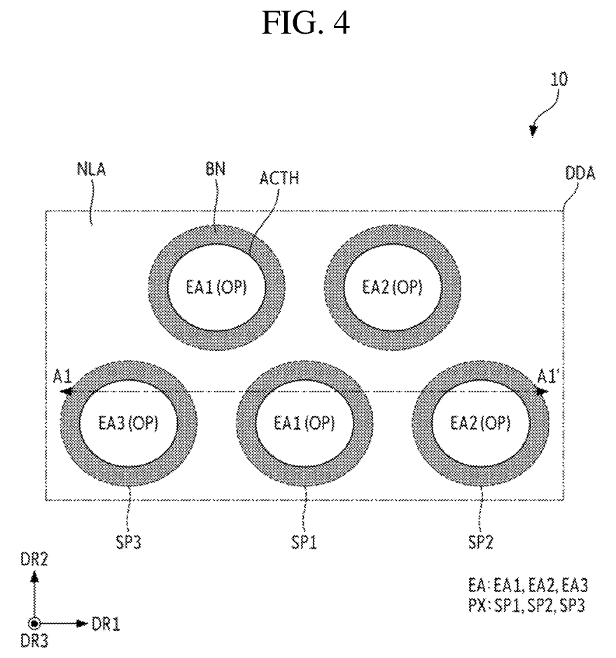

FIG. 4 is a layout (or plan view) view illustrating the arrangement of a plurality of pixels PX in the display area DDA of FIG. 3.

Referring to FIG. 4, each of the pixels PX of an embodiment may include a first subpixel SP1, a second subpixel SP2, and a third subpixel SP3 located in a portion overlapping the display area DDA. The first subpixel SP1, the second subpixel SP2, and the third subpixel SP3 may be spaced apart from each other.

The pixels PX may include emission areas EA. The emission areas EA may be portions (or planar areas) from which light is emitted. For example, the first subpixel SP1 may include a first emission area EA1, the second subpixel SP2 may include a second emission area EA2, and the third subpixel SP3 may include a third emission area EA3.

In an embodiment, the first emission area EA1, the second emission area EA2, and the third emission area EA3 may emit light of different colors. For example, the first emission area EA1 may emit red light, the second emission area EA2 may emit green light, and the third emission area EA3 may emit blue light. However, the present disclosure is not limited to this example. Depending on embodiments, the first emission area EA1, the second emission area EA2, and the third emission area EA3 can also emit light of the same color.

In an embodiment, the emission areas EA may be respectively defined by emission openings OP. The emission openings OP may be defined by a pixel defining layer PDL (see FIG. 5) which will be described later.

In a plan view, anode contact holes ACTH may be located in portions overlapping the emission areas EA and the emission openings OP. The anode contact holes ACTH will be described later.

The display device 10 of the embodiment may include a non-emission area NLA in the portion overlapping the display area DDA. The non-emission area NLA may surround the first emission area EA1, the second emission area EA2 and the third emission area EA3 and prevent color mixing of light emitted from the first emission area EA1, the second emission area EA2 and the third emission area EA3.

A bank structure BN may be located in a portion overlapping the non-emission area NLA. The bank structure BN may surround the emission openings OP or the anode contact holes ACTH.

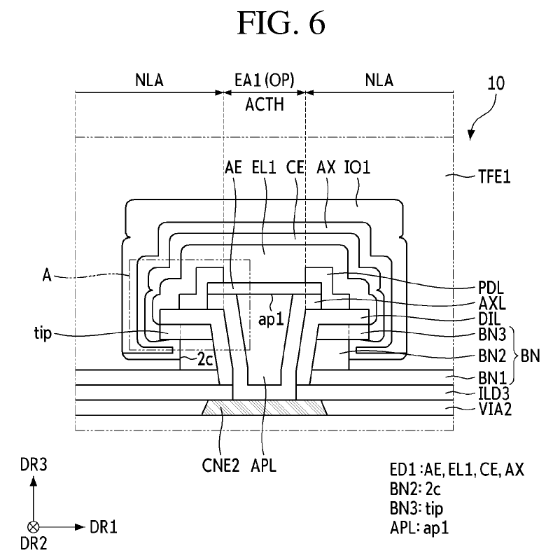

FIG. 5 is a cross-sectional view of an example of the display layer DPL taken along line A1-A1’ of FIG. 4. FIG. 6 is an enlarged cross-sectional view of the display element layer EML overlapping a first emission area EA1 in FIG. 5.

Referring to FIGS. 5 and 6, the transistor layer TFTL may be located on the substrate SUB. The transistor layer TFTL may include a first buffer layer BF1, bottom metal layers BML, a second buffer layer BF2, transistors TFT, a gate insulating layer GI, a first insulating layer ILD1, capacitor electrodes CPE, a second insulating layer ILD2, first connection electrodes CNE1, a first via layer VIA1, second connection electrodes CNE2, a second via layer VIA2, and a third insulating layer ILD3.

The first buffer layer BF1 may be located on the substrate SUB. The first buffer layer BF1 may include an inorganic layer that can prevent penetration of air or moisture. For example, the first buffer layer BF1 may include a plurality of inorganic layers stacked alternately.

The bottom metal layers BML may be located on the first buffer layer BF1. The bottom metal layers BML may include a conductive metal and may each be, for example, a single layer or a multilayer including any one or more of molybdenum (Mo), aluminum (Al), chromium (Cr), gold (Au), titanium (Ti), nickel (Ni), neodymium (Nd), copper (Cu), and alloys thereof.

The second buffer layer BF2 may cover the first buffer layer BF1 and the bottom metal layers BML. The second buffer layer BF2 may include an inorganic layer that can prevent penetration of air or moisture. For example, the second buffer layer BF2 may include a plurality of inorganic layers stacked alternately.

The transistors TFT may be located on the second buffer layer BF2. The transistors TFT may form pixel circuits. For example, each of the transistors TFT may be a driving transistor or a switching transistor of a pixel circuit.

Each of the transistors TFT may include an active layer ACT, a source electrode SE, a drain electrode DE, and a gate electrode GE.

The active layer ACT may be located on the second buffer layer BF2. The active layer ACT may be overlapped by the gate electrode GE in the third direction DR3 and may be insulated from the gate electrode GE by the gate insulating layer GI. The source electrode SE and the drain electrode DE may be formed by making portions of the active layer ACT conductive.

The gate insulating layer GI may be located on the active layers ACT. The gate insulating layer GI may cover the active layers ACT and the second buffer layer BF2 and may insulate the active layers ACT from the gate electrodes GE. The gate insulating layer GI may include contact holes through which the first connection electrodes CNE1 pass.

The gate electrodes GE may be located on the gate insulating layer GI. The gate electrodes GE may overlap the active layers ACT with the gate insulating layer GI. The gate insulating layer GI may be located between the gate electrodes GE and the active layers ACT.

The gate electrodes GE may include a conductive metal and may each be, for example, a single layer or a multilayer including any one or more of molybdenum (Mo), aluminum (Al), chromium (Cr), gold (Au), titanium (Ti), nickel (Ni), neodymium (Nd), copper (Cu), and alloys thereof.

The first insulating layer ILD1 may cover the gate electrodes GE and the gate insulating layer GI. The first insulating layer ILD1 may include contact holes through which the first connection electrodes CNE1 pass. The contact holes of the first insulating layer ILD1 may be connected to the contact holes of the gate insulating layer GI and contact holes of the second insulating layer ILD2.

The capacitor electrodes CPE may be located on the first insulating layer ILD1. The capacitor electrodes CPE may overlap the gate electrodes GE in the third direction DR3. The capacitor electrodes CPE and the gate electrodes GE may form capacitances.

The second insulating layer ILD2 may cover the capacitor electrodes CPE and the first insulating layer ILD1. The second insulating layer ILD2 may include the contact holes through which the first connection electrodes CNE1 pass. The contact holes of the second insulating layer ILD2 may be connected to the contact holes of the first insulating layer ILD1 and the contact holes of the gate insulating layer GI.

The first connection electrodes CNE1 may be located on the second insulating layer ILD2. The first connection electrodes CNE1 may electrically connect the drain electrodes DE of the transistors TFT to the second connection electrodes CNE2. The first connection electrodes CNE1 may be inserted into the contact holes formed in the first insulating layer ILD1, the second insulating layer ILD2, and the gate insulating layer GI to contact the drain electrodes DE of the transistors TFT.

The first via layer VIA1 may be located on the first connection electrodes CNE1 and the second insulating layer ILD2. The first via layer VIA1 may flatten structures under the first via layer VIA1. The first via layer VIA1 may include contact holes through which the second connection electrodes CNE2 pass.

The first via layer VIA1 may include an organic insulating material. For example, the first via layer VIA1 may include acrylic resin, polyimide, polyamide, benzocyclobutene, or phenolic resin.

The second connection electrodes CNE2 may be located on the first via layer VIA1. The second connection electrodes CNE2 may be located in portions overlapping emission areas EA. The second connection electrodes CNE2 may be inserted into the contact holes formed in the first via layer VIA1 to contact the first connection electrodes CNE1.

The second via layer VIA2 may be located on the first via layer VIA1. The second via layer VIA2 may flatten steps formed by the second connection electrodes CNE2.

The second via layer VIA2 may include an organic material. For example, the second via layer VIA2 may include acrylic resin, silicone resin, silicone acrylic resin, epoxy resin, polyimide, polyamide, benzocyclobutene, or phenolic resin.

The third insulating layer ILD3 may be located on the second via layer VIA2. The third insulating layer ILD3 may assist in preventing outgas caused by the organic material of the second via layer VIA2 from penetrating into the display element layer EML.

The third insulating layer ILD3 may include an inorganic insulating material. For example, the third insulating layer ILD3 may include at least one of silicon nitride, silicon oxide, and silicon oxynitride.

The display element layer EML may be located on the transistor layer TFTL. The display element layer EML may include the bank structure BN, an element insulating layer DIL, the pixel defining layer PDL, light emitting elements ED, anode auxiliary electrodes AXL, an anode planarization layer APL, and element inorganic layers IO.

The bank structure BN may be located on the third insulating layer ILD3. The bank structure BN may be located in a portion overlapping the non-emission area NLA. The bank structure BN may be located adjacent to the emission areas EA.

The bank structure BN may assist in positioning first through third light emitting elements ED1 through ED3 in portions overlapping first through third emission areas EA1 through EA3, respectively, and may assist in electrically connecting cathodes CE which are located in the first through third emission areas EA1 through EA3 and spaced apart from each other.

The bank structure BN may include a first bank layer BN1, a second bank layer BN2, and a third bank layer BN3. The first bank layer BN1, the second bank layer BN2, and the third bank layer BN3 may be sequentially stacked in the third direction DR3. Solid portions of a respective bank layer may be spaced apart from each other at the non-emission area NLA, such as to be formed as discrete patterns or islands. A first bank opening of the bank structure BN may be formed between the discrete patterns or islands, in the non-emission area NLA. A second bank opening may be an enclosed shape defined by a discrete pattern or the island. The second bank opening may overlap the emission area EA.

The first bank layer BN1 may be located on the third insulating layer ILD3. The first bank layer BN1 may cover the third insulating layer ILD3 in the portions overlapping the non-emission area NLA. The third insulating layer ILD3 within the emission areas EA may be uncovered by solid portions of the first bank layer BN1, such that portions of the third insulating layer ILD3 are exposed to outside the first bank layer BN1.

The first bank layer BN1 may assist in applying a low potential voltage to the cathodes CE. The first bank layer BN1 may include a conductive metal having etch resistance. For example, the first bank layer BN1 may include titanium (Ti).

The first bank layer BN1 may be penetrated by anode contact holes ACTH in the portions overlapping the emission areas EA. In other words, the first bank layer BN1 may surround the anode contact holes ACTH and may be formed in the form of a single conductive pattern surrounding the anode contact holes ACTH.

The second bank layer BN2 may be located on the first bank layer BN1 to contact the first bank layer BN1. The second bank layer BN2 may be penetrated by the anode contact holes ACTH. In other words, the second bank layer BN2 may surround the anode contact holes ACTH.

The second bank layer BN2 may be formed in multiple pieces, and the pieces of the second bank layer BN2 may be spaced apart from each other in the first direction DR1. In other words, the pieces of the second bank layer BN2 may be located surrounding the first through third emission areas EA1 through EA3, respectively, and may be spaced apart from each other in the form of islands at the non-emission area NLA.

The second bank layer BN2 may assist in electrically connecting the first bank layer BN1 to the third bank layer BN3. In other words, the second bank layer BN2 may be electrically connected to the first bank layer BN1 and the third bank layer BN3. Accordingly, the second bank layer BN2 located adjacent to the first emission area EA1, the second bank layer BN2 located adjacent to the second emission area EA2, and the second bank layer BN2 located adjacent to the third emission area EA3 may be electrically connected by the first bank layer BN1.

The second bank layer BN2 may include a metal having high electrical conductivity. For example, the second bank layer BN2 may include aluminum (Al).

The third bank layer BN3 may be located on the second bank layer BN2 to contact the second bank layer BN2. The third bank layer BN3 may be penetrated by the anode contact holes ACTH. In other words, the third bank layer BN3 may surround the anode contact holes ACTH.

The third bank layer BN3 may be formed in multiple pieces, and the pieces of the third bank layer BN3 may be spaced apart from each other in the first direction DR1. In other words, the pieces of the third bank layer BN3 may be located surrounding the first through third emission areas EA1 through EA3, respectively, and may be spaced apart from each other in the form of islands in the non-emission area NLA.

The third bank layer BN3 may include a conductive metal having etch resistance. For example, the third bank layer BN3 may be titanium (Ti).

In an embodiment, the third bank layer BN3 located adjacent to the first emission area EA1, the third bank layer BN3 located adjacent to the second emission area EA2, and the third bank layer BN3 located adjacent to the third emission area EA3 may be electrically connected through the second bank layer BN2 and the first bank layer BN1. Redundant descriptions are omitted.

As illustrated in FIG. 6, the second bank layer BN2 of an embodiment may include side surfaces 2c (e.g., an outer side surface) facing the non-emission area NLA, and the third bank layer BN3 may include tips protruding more than (e.g., further than) the side surfaces 2c of the second bank layer BN2 in the first direction DR1. Accordingly, the side surfaces 2c of the second bank layer BN2 and the tips of the third bank layer BN3 may form an undercut, and the bank structure BN may have an overhang structure open to the non-emission area NLA.

In the display device 10 of the embodiment, since the bank structure BN includes the tips, the first light emitting element ED1, the second light emitting element ED2, and the third light emitting element ED3 spaced apart from each other can be formed without using a fine metal mask in a fabrication process. The fabrication process will be described later.

An element insulating layer DIL may be located on the third bank layer BN3. The element insulating layer DIL may cover the third bank layer BN3.

The element insulating layer DIL may be penetrated by the anode contact holes ACTH in the portions overlapping the emission areas EA. In other words, the element insulating layer DIL may surround the anode contact holes ACTH.

The element insulating layer DIL may separate and insulate the bank structure BN from anodes AE so that they do not contact each other. Accordingly, the element insulating layer DIL may entirely cover side surfaces (e.g., inner side surfaces) of the bank structure BN which face the anode contact holes ACTH. Therefore, the element insulating layer DIL can solve a short circuit defect of the display device 10 caused by a contact between the anodes AE and the bank structure BN.

The element insulating layer DIL may include an inorganic insulating material. For example, the element insulating layer DIL may include at least one of silicon nitride, silicon oxide, and silicon oxynitride.

The pixel defining layer PDL may be located on the element insulating layer DIL. The pixel defining layer PDL may define emission openings OP and expose the anodes AE in portions overlapping the emission openings OP. In other words, the pixel defining layer PDL may surround the emission openings OP and cover edges of the anodes AE.

The pixel defining layer PDL may include an inorganic insulating material. For example, the pixel defining layer PDL may include at least one of silicon nitride, silicon oxide, and silicon oxynitride.

The anode auxiliary electrodes AXL may be located on the element insulating layer DIL. The anode auxiliary electrodes AXL may contact and cover the element insulating layer DIL and may extend to contact the second connection electrodes CNE2. The anode auxiliary electrodes AXL may be electrically connected to the second connection electrodes CNE2. In other words, the anode auxiliary electrodes AXL may entirely cover the element insulating layer DIL and the third insulating layer ILD3 and contact the second connection electrodes CNE2 in portions overlapping the anode contact holes ACTH.

Each of the anode auxiliary electrodes AXL may cover the element insulating layer DIL, the third insulating layer ILD3, and a second connection electrode CNE2 with a uniform thickness along the profile formed by the element insulating layer DIL, the third insulating layer ILD3, and the second connection electrode CNE2. Accordingly, each of the anode auxiliary electrodes AXL may include a step having the same shape as the structure under the anode auxiliary electrode AXL. The meaning of the uniform thickness mentioned above may include a process error of 10% or less. The thickness may be measured perpendicular to a surface on which the anode auxiliary electrode AXL is disposed so as to have the uniform thickness along the profile of the underlying layers which define the surface.

The anode auxiliary electrodes AXL may include a transparent conductive oxide (TCO). For example, the anode auxiliary electrodes AXL may include at least any one of indium-zinc-oxide (IZO) and indium-tin-oxide (ITO).

The light emitting elements ED of an embodiment may be located on the bank structure BN. The light emitting elements ED may overlap the bank structure BN in the third direction DR3. In addition, the light emitting elements ED may overlap the anode contact holes ACTH in the third direction DR3.

The display device 10 of the embodiment may be applied to a high-resolution electronic device. Therefore, a plurality of light emitting elements ED included in the display device 10 may be required to be placed within a narrow area with an appropriate distance between them. Accordingly, in the display device 10 of the embodiment, the light emitting elements ED may be formed on the bank structure BN so that they can be efficiently placed within a narrow area.

The light emitting elements ED may include the first light emitting element ED1 located in the first emission area EA1, the second light emitting element ED2 located in the second emission area EA2, and the third light emitting element ED3 located in the third emission area EA3. The first light emitting element ED1, the second light emitting element ED2, and the third light emitting element ED3 may be spaced apart from each other.

The first light emitting element ED1 may include an anode AE, a first light emitting layer EL1, a cathode CE, and a cathode auxiliary electrode AX. The second light emitting element ED2 may include an anode AE, a second light emitting layer EL2, a cathode CE, and a cathode auxiliary electrode AX. The third light emitting element ED3 may include an anode AE, a third light emitting layer EL3, a cathode CE, and a cathode auxiliary electrode AX.

The first light emitting element ED1, the second light emitting element ED2, and the third light emitting element ED3 may emit light of different colors. For example, the first light emitting element ED1 may emit red light, the second light emitting element ED2 may emit green light, and the third light emitting element ED3 may emit blue light. The colors of light emitted from the first light emitting element ED1, the second light emitting element ED2, and the third light emitting element ED3 may be determined by the first light emitting layer EL1, the second light emitting layer EL2, and the third light emitting layer EL3.

In an embodiment, the anode contact holes ACTH may be located in the portions overlapping the emission areas EA. The anode contact holes ACTH may be formed to penetrate the third insulating layer ILD3, the first bank layer BN1, the second bank layer BN2, and the third bank layer BN3.

In the display device 10 of the embodiment, the anode contact holes ACTH may be formed not in a separate space, but to overlap the emission areas EA so that contact areas of the anodes AE are integrated with the emission areas EA. Therefore, in the display device 10 of the embodiment, a plurality of emission areas EA can be efficiently placed within a narrow area.

The anodes AE may be located on the anode auxiliary electrodes AXL to contact the anode auxiliary electrodes AXL. The anode auxiliary electrodes AXL and the anodes AE may be electrically connected to each other.

The anodes AE may be exposed to outside the pixel defining layer PDL, in the portions overlapping the emission openings OP. The anodes AE may contact the first through third light emitting layers EL1 through EL3 in the portions overlapping the emission openings OP. The edges of the anodes AE which do not overlap the emission openings OP may be covered by the pixel defining layer PDL.

The anodes AE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or a mixture thereof. For example, the anodes AE may have, but are not limited to, a multilayer structure of ITO/Mg, ITO/MgF, ITO/Ag, or ITO/Ag/ITO.

In a process of fabricating (or providing) the display device 10, the anode auxiliary electrodes AXL and the anodes AE may be formed in different processes. Accordingly, a boundary surface may be formed between facing surfaces of the anode auxiliary electrodes AXL and the anodes AE. From the boundary surface (e.g., interface) formed between the facing surfaces of the anode auxiliary electrodes AXL and the anodes AE in the display device 10 of the embodiment, it can be seen that the anode auxiliary electrodes AXL and the anodes AE are formed in different processes.

The anode planarization layer APL may be located between the anode auxiliary electrodes AXL and the anodes AE. The anode planarization layer APL may contact the anode auxiliary electrodes AXL and the anodes AE. The anode planarization layer APL may be completely surrounded by the anode auxiliary electrodes AXL and the anodes AE. A space may be formed by an anode auxiliary electrodes AXL contacting an anode AE.

The anode planarization layer APL may be located in each of the anode contact holes ACTH. The anode planarization layer APL may flatten a step included in an anode auxiliary electrode AXL in the portion overlapping each anode contact hole ACTH.

In an embodiment, an overall anode may be defined by the anode auxiliary electrode AXL and the anode AE in contact with each other. The anode contact hole ACTH may be defined by a planar area of the anode electrode AE which is exposed to outside the pixel defining layer PDL. The anode contact hole ACTH may be defined at the emission opening OP, such as where the interface between facing surfaces of the anode auxiliary electrode AXL and the anode AE is defined.

For example, if the display device 10 does not include the anode planarization layer APL, each anode AE may include a step corresponding to the shape of an anode auxiliary electrode AXL. For example, if each anode AE includes a step corresponding to the shape of an anode auxiliary electrode AXL or the shape of an anode contact hole ACTH, a reliability defect (e.g., a non-uniform thickness defect or a contact defect) of the anode AE may occur.

Therefore, the display device 10 of the embodiment may help each anode AE have a relatively flat shape by including the anode planarization layer APL in the portion overlapping each anode contact hole ACTH. Accordingly, the display device 10 of the embodiment can solve a reliability defect of the anodes AE.

The anode planarization layer APL may include an organic material. For example, the anode planarization layer APL may include acrylic resin, silicone resin, silicone acrylic resin, epoxy resin, polyimide, polyamide, benzocyclobutene, or phenolic resin.

In the process of fabricating the display device 10 of the embodiment, the anode planarization layer APL may be formed by performing a chemical mechanical polishing (CMP) process. The fabrication process will be described later.

In an embodiment, the anode planarization layer APL may include a first surface ap1 facing each anode AE. The first surface ap1 of the anode planarization layer APL may have various shapes depending on process conditions. The first surface ap1 of the anode planarization layer APL may be convex in a direction toward one side in the third direction DR3 or may be concave in a direction toward the other side in the third direction DR3. In addition, the anode planarization layer APL may cover a portion of an upper surface of the element insulating layer DIL. The present specification does not limit the shape of the first surface ap1 of the anode planarization layer APL.

The first through third light emitting layers EL1 through EL3 may be located on the anodes AE. The first through third light emitting layers EL1 through EL3 may be located in the portions overlapping the emission areas EA and the non-emission area NLA. The first through third light emitting layers EL1 through EL3 may overlap the bank structure BN in the third direction DR3.

The first through third light emitting layers EL1 through EL3 may contact the anodes AE in the portions overlapping the emission openings OP and may cover the entire pixel defining layer PDL in the portion overlapping the non-emission area NLA.

The first through third light emitting layers EL1 through EL3 may be organic light emitting layers including an organic material. The first through third light emitting layers EL1 through EL3 may include any commonly used material.

The first light emitting layer EL1, the second light emitting layer EL2, and the third light emitting layer EL3 may emit light of different colors. For example, the first light emitting layer EL1 may emit red light, the second light emitting layer EL2 may emit green light, and the third light emitting layer EL3 may emit blue light, but the present disclosure is not limited to this example.

The first light emitting layer EL1 may be located in the portion overlapping the first emission area EA1, the second light emitting layer EL2 may be located in the portion overlapping the second emission area EA2, and the third light emitting layer EL3 may be located in the portion overlapping the third emission area EA3. The first light emitting layer EL1, the second light emitting layer EL2, and the third light emitting layer EL3 may be spaced apart from each other in the portion overlapping the non-emission area NLA.

In the display device 10 of the embodiment, since the third bank layer BN3 includes the tips, the first light emitting layer EL1, the second light emitting layer EL2, and the third light emitting layer EL3 spaced apart from each other can be formed by a photolithography process without using a fine metal mask in the fabrication process. The fabrication process will be described later.

The cathodes CE may be located on the first through third light emitting layers EL1 through EL3. The cathodes CE may be located in the portions overlapping the emission areas EA and the non-emission area NLA. The cathodes CE may entirely cover the first through third light emitting layers EL1 through EL3.

The cathodes CE may contact the bank structure BN and thus may be electrically connected to the bank structure BN. Specifically, the cathodes CE may contact the tips of the third bank layer BN3.

The cathodes CE may include a transparent conductive material to transmit light generated from the first through third light emitting layers EL1 through EL3. For example, the cathodes CE may include a material layer having a small work function such as Li, Ca, LiF/Ca, LiF/Al, Al, Mg, Ag, Pt, Pd, Ni, Au Nd, Ir, Cr, BaF, Ba, or a compound or mixture thereof (e.g., a mixture of Ag and Mg). The cathodes CE may further include a transparent metal oxide layer located on the material layer having a small work function.

In an embodiment, the cathode CE located in the portion overlapping the first emission area EA1, the cathode CE located in the portion overlapping the second emission area EA2, and the cathode CE located in the portion overlapping the third emission area EA3 may be spaced apart from each other. The cathodes CE located in the first through third emission areas EA1 through EA3, respectively, and spaced apart from each other may be electrically connected through the bank structure BN. Specifically, the cathodes CE located in the first through third emission areas EA1 through EA3, respectively, and spaced apart from each other may contact the pieces of the third bank layer BN3 located in the first through third emission areas EA1 through EA3, respectively, and spaced apart from each other and may be electrically connected to each other through the second bank layer BN2 and the first bank layer BN1 electrically connected to the third bank layer BN3.

In the display device 10 of the embodiment, since the third bank layer BN3 includes the tips, the cathodes CE located in the first through third emission areas EA1 through EA3, respectively, and spaced apart from each other can be formed by a photolithography process without using a fine metal mask. The fabrication process will be described later.

The cathode auxiliary electrodes AX may be located on the cathodes CE. The cathode auxiliary electrodes AX may be located in the portions overlapping the emission areas EA and the non-emission area NLA. The cathode auxiliary electrodes AX may entirely cover the cathodes CE. The cathode auxiliary electrodes AX may assist in electrically connecting the cathodes CE. An overall cathode may include a cathode auxiliary electrode AX in contact with a cathode CE.

The cathode auxiliary electrodes AX may include a transparent conductive oxide (TCO). For example, the cathode auxiliary electrodes AX may include at least any one of indium-zinc-oxide (IZO) and indium-tin-oxide (ITO).

In an embodiment, the cathode auxiliary electrodes AX and the cathodes CE may be formed integrally with each other.

In an embodiment, the cathode auxiliary electrode AX located in the portion overlapping the first emission area EA1, the cathode auxiliary electrode AX located in the portion overlapping the second emission area EA2, and the cathode auxiliary electrode AX located in the portion overlapping the third emission area EA3 may be spaced apart from each other. The cathode auxiliary electrodes AX located in the first through third emission areas EA1 through EA3, respectively, and spaced apart from each other may be electrically connected through the bank structure BN. Specifically, the cathode auxiliary electrodes AX located in the first through third emission areas EA1 through EA3, respectively, and spaced apart from each other may contact the pieces of the second bank layer BN2 and the third bank layer BN3 located in the first through third emission areas EA1 through EA3, respectively, and spaced apart from each other and may be electrically connected to each other through the first bank layer BN1 electrically connected to the second bank layer BN2.

The cathode auxiliary electrodes AX may be spaced apart from the first bank layer BN1 in the third direction DR3 in the portion overlapping the non-emission area NLA. This may be because, during the process of fabricating the display device 10, a material that forms the light emitting layers EL and a material that forms the cathodes CE are temporarily formed between the first bank layer BN1 and the cathode auxiliary electrodes AX and then removed by a subsequent process. The fabrication process will be described later.

The element inorganic layers IO may be located on the light emitting elements ED. The element inorganic layers IO may completely cover the light emitting elements ED and prevent oxygen or moisture from penetrating into the light emitting elements ED.

The element inorganic layers IO may include an inorganic insulating material. For example, the element inorganic layers IO may include any one of silicon nitride, silicon oxide, and silicon oxynitride.

The element inorganic layers IO may include a first element inorganic layer IO1, a second element inorganic layer IO2, and a third element inorganic layer IO3 as respective element inorganic patterns of an element inorganic layer. The first element inorganic layer IO1 may be located on the first light emitting element ED1 in the first emission area EA1, the second element inorganic layer IO2 may be located on the second light emitting element ED2 in the second emission area EA2, and the third element inorganic layer IO3 may be located on the third light emitting element ED3 in the third emission area EA3. The first element inorganic layer IO1, the second element inorganic layer IO2, and the third element inorganic layer IO3 may be spaced apart from each other in the portion overlapping the non-emission area NLA.

In the drawings, the first element inorganic layer IO1, the second element inorganic layer IO2, and the third element inorganic layer IO3 appear to be formed in the same layer, without being limited thereto. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto. However, in the process of fabricating the display device 10, the first element inorganic layer IO1 may be formed after the first light emitting element ED1 is formed, the second element inorganic layer IO2 may be formed after the second light emitting element ED2 is formed, and the third element inorganic layer IO3 may be formed after the third light emitting element ED3 is formed. The fabrication process will be described later.

A light emitting element structure may include the patterns of layers from AXL to IO inclusive, without being limited thereto.

The thin-film encapsulation layer TFEL may be located on the display element layer EML. The thin-film encapsulation layer TFEL may include an organic encapsulation layer TFE1 and an inorganic encapsulation layer TFE3.

The organic encapsulation layer TFE1 of an embodiment may be located on the element inorganic layers IO. For example, the organic encapsulation layer TFE1 may entirely contact and cover the first element inorganic layer IO1, the second element inorganic layer IO2, and the third element inorganic layer IO3.

The organic encapsulation layer TFE1 may flatten steps formed according to the profiles of structures under the organic encapsulation layer TFE1. The organic encapsulation layer TFE1 may fill portions between the cathode auxiliary electrodes AX and the first bank layer BN1 in the portion overlapping the non-emission area NLA.

The organic encapsulation layer TFE1 may include a polymer-based material. For example, the organic encapsulation layer TFE1 may include acrylic resin, silicone resin, epoxy resin, silicone acrylic resin, polyimide, or polyethylene.

The inorganic encapsulation layer TFE3 may be located on the organic encapsulation layer TFE1. The inorganic encapsulation layer TFE3 may protect structures under the inorganic encapsulation layer TFE3 from penetration of moisture and oxygen. The inorganic encapsulation layer TFE3 can be omitted depending on embodiments.

The inorganic encapsulation layer TFE3 may include an inorganic insulating material. For example, the inorganic encapsulation layer TFE3 may include any one of silicon nitride, silicon oxide, and silicon oxynitride.

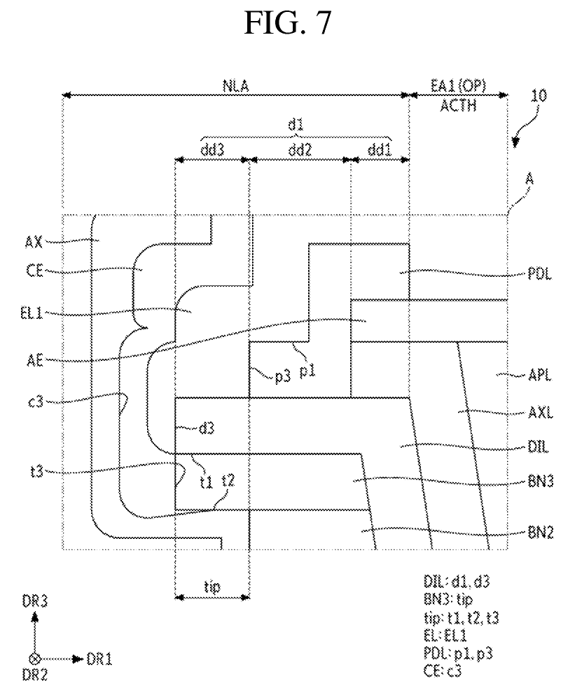

FIG. 7 is an enlarged cross-sectional view of area ‘A’ in FIG. 6.

Referring to FIG. 7 in addition to FIGS. 1 through 6, in an embodiment, a tip of the third bank layer BN3 may include an upper surface t1, a lower surface t2, and a side surface t3. The upper surface t1 may be a surface facing the element insulating layer DIL, and the lower surface t2 may be a surface opposite the upper surface t1. The side surface t3 may be located in a direction toward the non-emission area NLA and may be a surface connecting the upper surface t1 and the lower surface t2.

In some embodiments, the element insulating layer DIL of an embodiment may overlap the tip of the third bank layer BN3 and may cover the entire upper surface t1 of the tip.

In an embodiment, the element insulating layer DIL may include an upper surface d1 and a side surface d3. The upper surface d1 of the element insulating layer DIL may be a surface facing the pixel defining layer PDL, and the side surface d3 may be located in the direction toward the non-emission area NLA.

In some embodiments, the side surface d3 of the element insulating layer DIL may be located on the same line as the side surface t3 of the tip included in the third bank layer BN3. In other words, the side surface d3 of the element insulating layer DIL may be aligned with the side surface t3 of the tip. As being aligned, the surfaces d3 and t3 may be coplanar with each other (e.g., along a DR2-DR3 plane).

In an embodiment, the element insulating layer DIL and the pixel defining layer PDL may include staircase-like steps. Specifically, the upper surface d1 of the element insulating layer DIL of the embodiment may include a first portion dd1, a second portion dd2, and a third portion dd3 depending on the structure that the upper surface d1 of the element insulating layer DIL contacts. The first portion dd1 may be a portion in contact with an anode auxiliary electrode AXL, the second portion dd2 may be a portion in contact with the pixel defining layer PDL, and the third portion dd3 may be a portion in contact with a light emitting layer EL. The second portion dd2 may be located between the first portion dd1 and the third portion dd3. In other words, a portion of the upper surface d1 of the element insulating layer DIL may contact the light emitting layer EL.

The pixel defining layer PDL may include an upper surface p1 and a side surface p3. The upper surface p1 of the pixel defining layer PDL may be a surface facing the light emitting layer EL, and the side surface p3 may be located in the direction toward the non-emission area NLA.

The side surface p3 of the pixel defining layer PDL of an embodiment may be spaced apart from the side surface t3 of the tip included in the third bank layer BN3 in a direction toward an anode contact hole ACTH. In other words, the pixel defining layer PDL may not overlap a portion of the tip of the third bank layer BN3 in the third direction DR3.

In some embodiments, the side surface p3 of the pixel defining layer PDL may be spaced apart from the side surface d3 of the element insulating layer DIL in the direction toward the anode contact hole ACTH.

In an embodiment, the light emitting layer EL may entirely contact and cover the upper surface p1 and the side surface p3 of the pixel defining layer PDL. In addition, the light emitting layer EL may extend to contact and cover the third portion dd3 included in the upper surface d1 of the element insulating layer DIL. According to an embodiment, the light emitting layer EL may contact and cover the side surface d3 of the element insulating layer DIL.

The light emitting layer EL of an embodiment may include staircase-like steps in the portion overlapping the non-emission area NLA because the pixel defining layer PDL and the element insulating layer DIL include the staircase-like steps (e.g., a multi-stepped .

In an embodiment, a cathode CE may entirely cover the light emitting layer EL. In addition, the cathode CE may extend to contact at least any one of the side surface t3 and the lower surface t2 of the tip included in the third bank layer BN3. Accordingly, the cathode CE may be electrically connected to the third bank layer BN3.

The cathode CE of an embodiment may include steps in the portion overlapping the non-emission area NLA because the pixel defining layer PDL and the element insulating layer DIL include the staircase-like steps. This will be described in detail later.

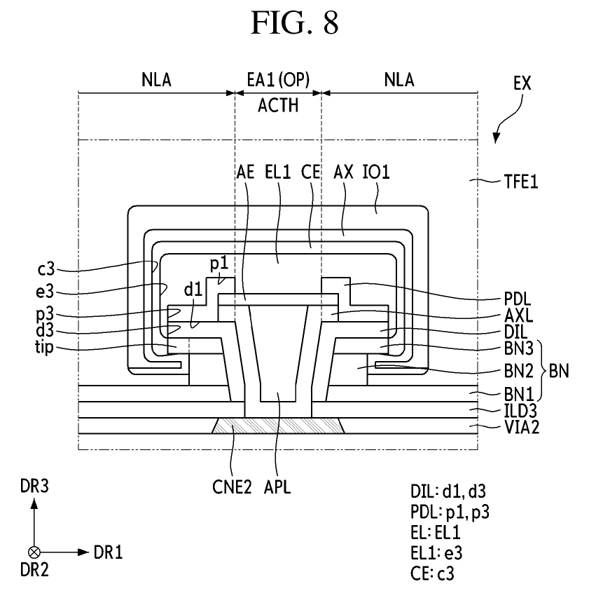

FIG. 8 is an enlarged cross-sectional view of a display element layer overlapping the first emission area EA1 in FIG. 5 according to a comparative example EX. A description of common structures of the comparative example EX and the display device 10 will be omitted, and differences will be described below.

Referring to FIG. 8 in addition to FIGS. 1 through 7, a pixel defining layer PDL of the comparative example EX may cover the entire upper surface d1 of an element insulating layer DIL. Accordingly, side surfaces d3 included in the element insulating layer DIL of the comparative example EX may be located on the same line as side surfaces p3 of the pixel defining layer PDL. The pixel defining layer PDL of the comparative example EX may overlap tips included in a third bank layer BN3.

A light emitting layer EL of the comparative example EX may entirely cover an upper surface p1 and the side surfaces p3 of the pixel defining layer PDL and may extend to include the side surfaces d3 of the element insulating layer DIL. The light emitting layer EL of the comparative example EX may not contact the upper surface d1 of the element insulating layer DIL.

The light emitting layer EL of the comparative example EX may not include a step in a portion overlapping the non-emission area NLA, since surfaces t3, d3 and p3 are aligned. Accordingly, each side surface e3 included in the light emitting layer EL of the comparative example EX may have a surface extending in a direction toward one side in the third direction DR3. In other words, the side surfaces e3 included in the light emitting layer EL may extend in a direction perpendicular to a surface of the substrate SUB. In other words, the side surfaces e3 included in the light emitting layer EL may have a high taper angle with respect to the surface of the substrate SUB.

A cathode CE of the comparative example EX may cover the light emitting layer EL and contact the tips of the third bank layer BN3. The cathode CE of the comparative example EX may cover the light emitting layer EL along the side surfaces e3 of the light emitting layer EL. Accordingly, each side surface c3 included in the cathode CE of the comparative example EX may have a surface extending in the third direction DR3. In other words, the side surfaces c3 included in the cathode CE may extend in the direction perpendicular to the surface of the substrate SUB. The side surfaces c3 included in the cathode CE may have a high taper angle with respect to the surface of the substrate SUB.

For example, when the side surfaces c3 of the cathode CE have a high taper angle with respect to the surface of the substrate SUB, a short circuit defect of the cathode CE may occur. The short circuit defect of the cathode CE may be caused by the deterioration of step coverage characteristics of a material that forms the cathode CE when the cathode CE is formed during a fabrication process.

Referring again to FIGS. 6 and 7, in the display device 10 of the embodiment, since the lower stacked structure as the pixel defining layer PDL and the element insulating layer DIL are formed to include staircase-like steps, the cathode CE within an upper stacked structure may include staircase-like steps in the portion overlapping the non-emission area NLA. That is, each side surface c3 of the cathode CE of the embodiment may include a plurality of steps in the portion overlapping the non-emission area NLA, and the display device 10 may minimize a section in which each side surface c3 of the cathode CE has a high taper angle. Therefore, the display device 10 of the embodiment can solve a short circuit defect of the cathode CE.

In an embodiment, the staircase-like steps formed by the pixel defining layer PDL and the element insulating layer DIL may be formed using a photoresist which is formed using a halftone mask in the process of fabricating the display device 10. The fabrication process will be described later.

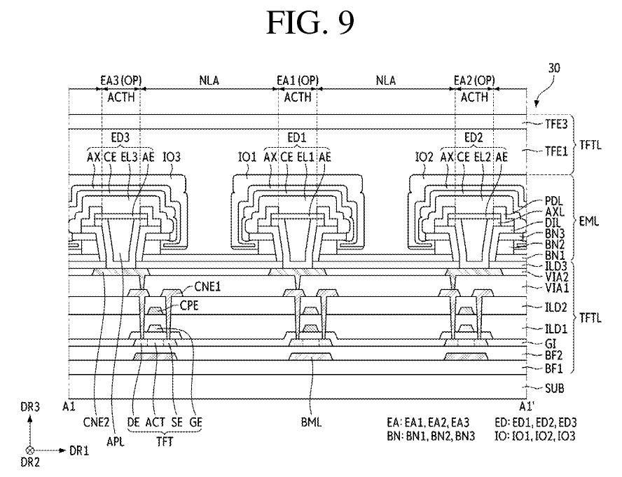

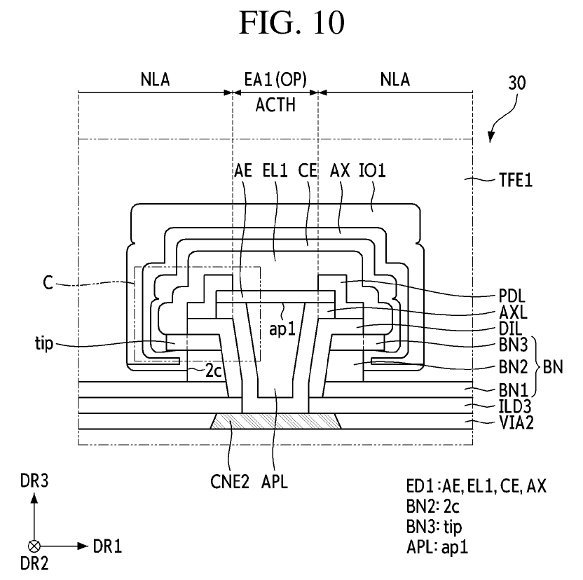

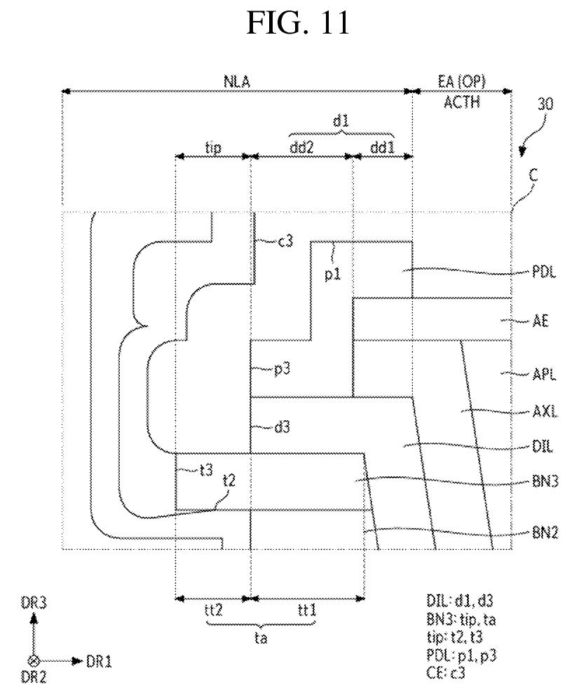

FIG. 9 is a cross-sectional view of an example of the display layer taken along line A1-A1’ of FIG. 4. FIG. 10 is an enlarged cross-sectional view of a display element layer EML overlapping a first emission area EA1 in FIG. 9. FIG. 11 is an enlarged cross-sectional view of area ‘C’ in FIG. 10.

Referring to FIGS. 9 through 11 in addition to FIGS. 1 through 8, the structure of the display element layer EML included in a display device 30 may be partially different from the structure of the display element layer EML included in the display device 10. A description of the same structures included in the display device 10 and the display device 30 will be omitted, and differences will be described below.

A third bank layer BN3 included in the display device 30 may include an upper surface ta facing an element insulating layer DIL. The upper surface ta included in the third bank layer BN3 may be a surface facing the element insulating layer DIL.

The element insulating layer DIL and the third bank layer BN3 included in the display device 30 may include staircase-like steps. Specifically, the upper surface ta included in the third bank layer BN3 included in the display device 30 may include a first portion tt1 and a second portion tt2 depending on the structure that the upper surface ta of the third bank layer BN3 contacts. The first portion tt1 may be a portion in contact with the element insulating layer DIL, and the second portion tt2 may be a portion in contact with a light emitting layer EL.

Each side surface d3 of the element insulating layer DIL included in the display device 30 may be spaced apart from a side surface t3 included in a tip of the third bank layer BN3 in a direction toward an anode contact hole ACTH. In other words, the element insulating layer DIL included in the display device 30 may not overlap a portion of each tip of the third bank layer BN3 in the third direction DR3.

Each side surface p3 of a pixel defining layer PDL included in the display device 30 may be spaced apart from the side surface t3 of the tip included in the third bank layer BN3 in the direction toward the anode contact hole ACTH. In other words, the pixel defining layer PDL may not overlap a portion of each tip of the third bank layer BN3 in the third direction DR3.

In some embodiments, the side surfaces p3 of the pixel defining layer PDL included in the display device 30 may be located on the same line as the side surfaces d3 of the element insulating layer DIL. In other words, the side surfaces p3 of the pixel defining layer PDL included in the display device 30 and the side surfaces d3 of the element insulating layer DIL may be aligned.

Each light emitting layer EL included in the display device 30 may entirely contact and cover an upper surface p1 and the side surfaces p3 of the pixel defining layer PDL. In addition, each light emitting layer EL included in the display device 30 may extend to contact and cover the side surfaces d3 of the element insulating layer DIL and the second portion tt2 included in the upper surface ta of the third bank layer BN3.

Each light emitting layer EL included in the display device 30 may include steps in a portion overlapping a non-emission area NLA because the element insulating layer DIL and the third bank layer BN3 form staircase-like steps.

Each cathode CE included in the display device 30 may entirely cover a light emitting layer EL and may extend to contact at least any one of a side surface t3 and a lower surface t2 of each tip included in the third bank layer BN3. Accordingly, the cathodes CE may be electrically connected to the third bank layer BN3.

In the display device 30, since staircase-like steps are formed between the third bank layer BN3 and the element insulating layer DIL, each cathode CE may be formed to include staircase-like steps in the portion overlapping the non-emission area NLA. Accordingly, each side surface c3 of each cathode CE may include a plurality of steps in the portion overlapping the non-emission area NLA, and the display device 30 may minimize a section in which each side surface c3 of each cathode CE has a high taper angle. Accordingly, the display device 30 can solve a short circuit defect of the cathodes CE.

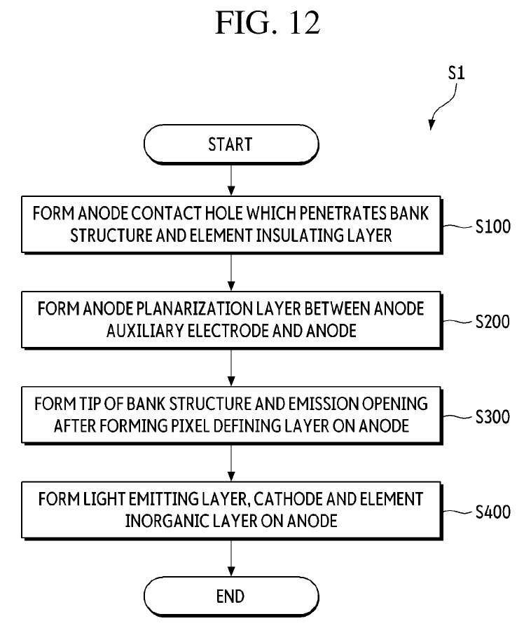

FIG. 12 is a flowchart illustrating a method S1 of fabricating (or providing) the display element layer EML in FIG. 5.

Referring to FIG. 12 in addition to FIGS. 1 through 11, the method S1 of fabricating the display element layer EML included in a display device according to an embodiment may include forming an anode contact hole which penetrates a bank structure and an element insulating layer (operation S100), forming an anode planarization layer between an anode auxiliary electrode and an anode (operation S200), forming a tip of the bank structure and an emission opening after forming a pixel defining layer on the anode (operation S300), and forming a light emitting layer, a cathode and an element inorganic layer on the anode (operation S400).

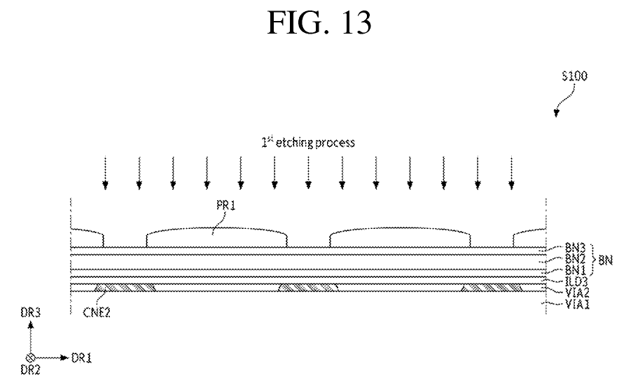

FIGS. 13 through 16 are cross-sectional views illustrating operation S100 of FIG. 12.

The forming of the anode contact hole which penetrates the bank structure and the element insulating layer (operation S100) will be described with reference to FIGS. 13 through 16.

First, a plurality of second connection electrodes CNE2 are formed on a first via layer VIA1, and then material layers forming a second via layer VIA2, a third insulating layer ILD3 and a bank structure BN are formed over the entire surface of the second connection electrode layer and the first via layer VIA1. The bank structure BN may include a first bank layer BN1, a second bank layer BN2 and a third bank layer BN3 stacked sequentially. Each of the layers may form a thickness portion of an overall bank of a bank layer.

In the current process, the second bank layer BN2 and the third bank layer BN3 may include different materials. For example, the third bank layer BN3 may include a material having higher etch resistance than that of the second bank layer BN2. Redundant descriptions are omitted.

Although not illustrated in the drawings, a thin-film transistor layer TFTL including the first via layer VIA1 and the second via layer VIA2 may be located on a substrate SUB. The detailed structure of the thin-film transistor layer TFTL is the same as that illustrated in FIG. 5.

Next, photoresists PR1 are formed on the third bank layer BN3, and a first etching process is performed. In the current process, a plurality of photoresists PR1 may be formed and may be spaced apart from each other in portions overlapping the second connection electrodes CNE2.

In the current process, the first etching process may be performed as a dry etching process. For example, the dry etching process may be performed through a reactive ion etching (RIE) process using a reaction gas such as CHF₃, CH₃F, CH₂F₂, CHF₆, CF₄, C₂F₆ or C₃F₆ and a sputtering gas such as Ar or O₂/Ar. In this case, an inductively coupled plasma (ICP) source or a capacitively coupled plasma (CCP) source may be used as a plasma source.

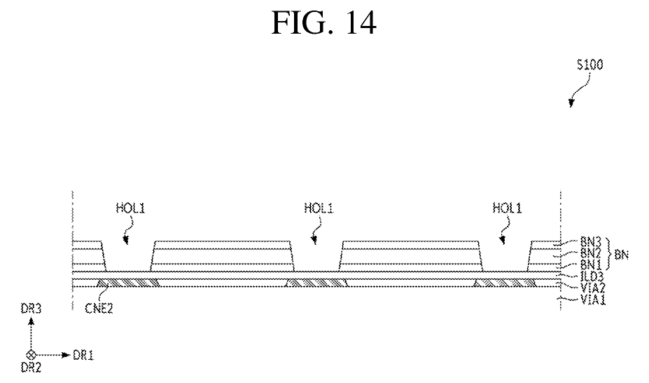

As illustrated in FIG. 14, through the current process, the bank structure BN not overlapped by the photoresists PR1 may all be removed at once to form holes HOL1 corresponding to anode contact holes ACTH to be described later. Side surfaces of the first bank layer BN1, side surfaces of the second bank layer BN2, and side surfaces of the third bank layer BN3 which face the holes HOL1 may be located on the same line (e.g., coplanar with each other). The third insulating layer ILD3 may be exposed to outside the bank layers in portions overlapping the holes HOL1.

Although not illustrated in the drawings, the photoresists PR1 may be removed through an ashing process.

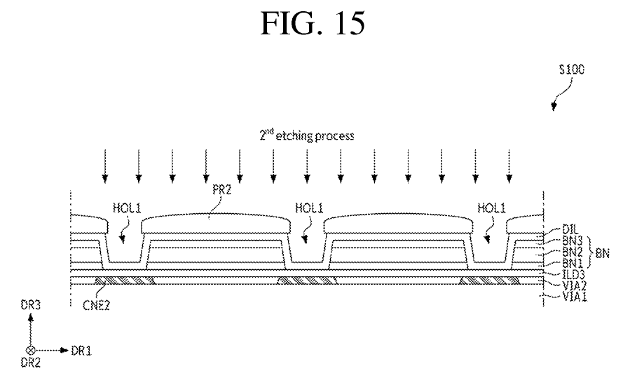

Next, as illustrated in FIG. 15, a material layer for forming an element insulating layer DIL is formed on the bank structure BN. The material layer of the element insulating layer DIL may be formed over the entire surface and may entirely cover the side surfaces of the first bank layer BN1, the side surfaces of the second bank layer BN2 and the side surfaces of the third bank layer BN3 which face the holes HOL1. In addition, the material layer of the element insulating layer DIL may extend to cover exposed portions of the third insulating layer ILD3 in the portions overlapping the holes HOL1.

In the current process, the element insulating layer DIL may be formed through a layer forming process (e.g., a deposition process) for forming at least one of the inorganic materials described above.

Next, photoresists PR2 are formed on the element insulating layer DIL, and a second etching process is performed. A plurality of photoresists PR2 may be formed and may be spaced apart from each other in the portions overlapping the holes HOL1. For example, the second etching process may be performed as a dry etching process. Redundant descriptions are omitted.

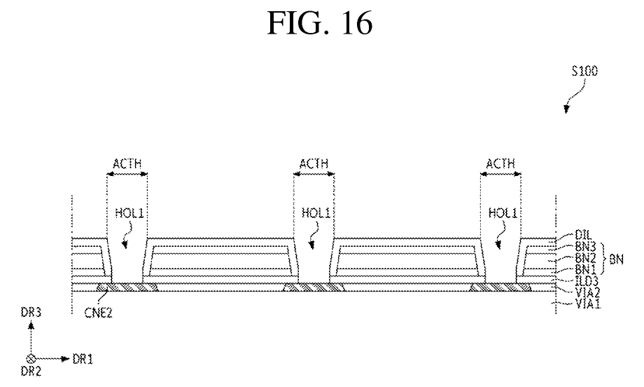

As illustrated in FIG. 16, in the current process, the element insulating layer DIL and the third insulating layer ILD3 not overlapped by the photoresists PR2 may all be removed at once. As a result, anode contact holes ACTH may be formed as including thickness portions at the third insulating layer ILD3, the bank structure BN and the element insulating layer DIL. The second connection electrodes CNE2 may be exposed in portions overlapping the anode contact holes ACTH.

Although not illustrated in the drawings, the photoresists PR2 may be removed through an ashing process.

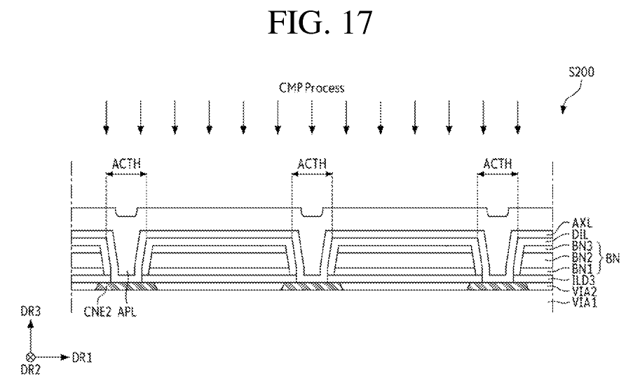

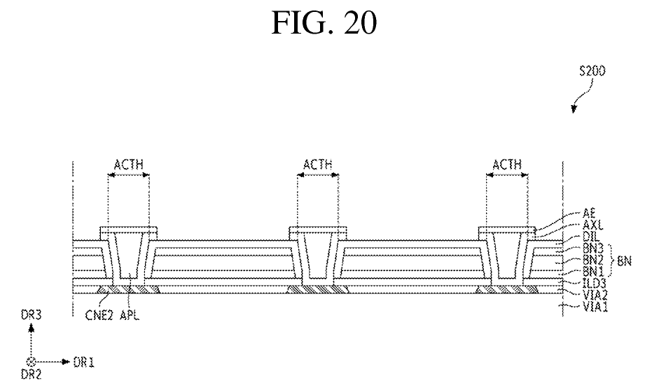

FIGS. 17 through 20 are cross-sectional views illustrating operation S200 of FIG. 12.

The forming of the anode planarization layer between the anode auxiliary electrode and the anode (operation S200) will be described with reference to FIGS. 17 through 20.

First, a material layer for forming an anode auxiliary electrode AXL is formed on the element insulating layer DIL. The material layer of the anode auxiliary electrode AXL may entirely contact and cover the second connection electrodes CNE2 exposed in the portions overlapping the anode contact holes ACTH and may extend to entirely cover the element insulating layer DIL. The material layer of the anode auxiliary electrode AXL may be spaced apart from the bank structure BN by the element insulating layer DIL.

The material layer of the anode auxiliary electrode AXL may be formed with a uniform thickness along the profile of a structure under the anode auxiliary electrode AXL. Accordingly, the anode auxiliary electrode AXL may include a step in the portions overlapping the anode contact holes ACTH.

In the current process, the anode auxiliary electrode AXL may be formed through a layer forming process (e.g., sputtering) for forming at least one of the metal materials described above.

Next, a material layer for forming an anode planarization layer APL is formed on the material layer of the anode auxiliary electrode AXL. The anode planarization layer APL may have a greater thickness than the step formed by the anode auxiliary electrode AXL in the portions overlapping the anode contact holes ACTH. Therefore, the anode planarization layer APL may flatten the step formed by the anode auxiliary electrode AXL.

In the current process, the anode planarization layer APL may be formed by a coating process (e.g., inkjet, printing, etc.) for forming at least one of the organic materials described above.

Next, a chemical-mechanical polishing (CMP) process is performed. For example, the CMP process refers to a process of planarizing an irregular or uneven surface by polishing the surface using chemical/mechanical elements. For example, in the current process, the CMP process may be performed as an organic layer CMP process.

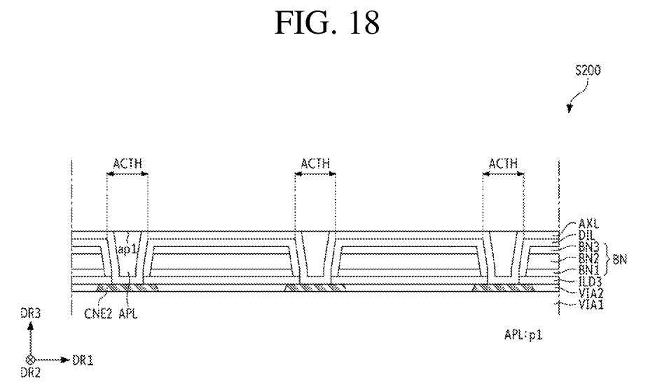

As illustrated in FIG. 18, through the current process, an upper thickness portion of the anode planarization layer APL may be polished and removed, and the anode planarization layer APL may have a first surface ap1 in the portions overlapping the anode contact holes ACTH. The first surface ap1 of the anode planarization layer APL may have various shapes depending on the conditions under which the process is performed.

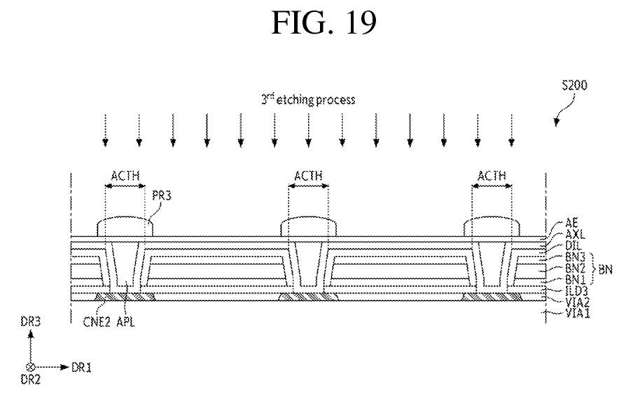

Next, referring to FIG. 19, a material layer for forming an anode AE is formed on the anode auxiliary electrode AXL and the anode planarization layer APL. The material layer of the anode AE may be formed over the entire surface and may completely cover the anode auxiliary electrode AXL and the anode planarization layer APL.

In the current process, the anode AE may be formed through a layer forming process (e.g., sputtering) for forming at least one of the metal materials described above.

Next, photoresists PR3 are formed on the anode AE, and a third etching process is performed. In the current process, a plurality of photoresists PR3 may be formed and may be located in the portions overlapping the anode contact holes ACTH. For example, the third etching process may be performed through at least any one of a dry etching process and a wet etching process.

In an example, the wet etching process may be performed using a liquid chemical solution such as a diluted hydrofluoric acid solution, a nitric acid solution, a tetramethylammonium hydroxide solution, or a potassium hydroxide solution.

Through the current process, the anode auxiliary electrode AXL and the anode AE not overlapped by the photoresists PR3 may be removed. Accordingly, the anode auxiliary electrode AXL and the anode AE may be patterned.

In the current process, the element insulating layer DIL not overlapped by the anodes AE and the anode auxiliary electrodes AXL may be exposed.

Although not illustrated in the drawings, the photoresists PR3 may be removed through an ashing process.

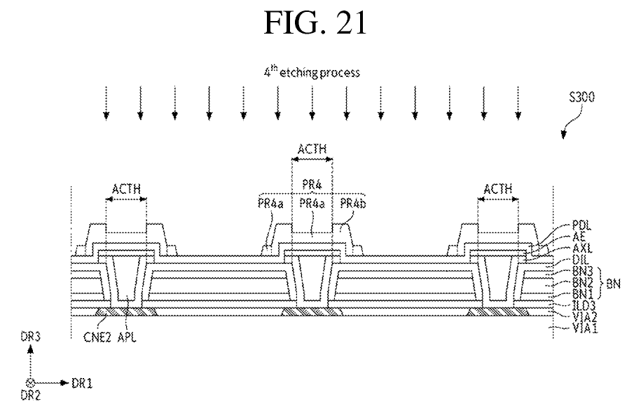

FIGS. 21 through 26 are cross-sectional views illustrating operation S300 of FIG. 12.

The forming of the tip of the bank structure and the emission opening after the forming of the pixel defining layer on the anode (operation S300) will be described with reference to FIGS. 21 through 26.

First, a material layer for forming a pixel defining layer PDL is formed on the anodes AE and the element insulating layer DIL. The material layer of the pixel defining layer PDL may be formed over the entire surface.

In current process, the pixel defining layer PDL may be formed through a layer forming process (e.g., a deposition process) for forming at least one of the inorganic materials described above.

Next, photoresists PR4 are formed on the pixel defining layer PDL, and a fourth etching process is performed. For example, in the fourth etching process, a dry etching process and a wet etching process may be alternately performed.

In current process, the photoresists PR4 may be formed using a halftone mask. For example, the photoresists PR4 may be formed to include a specific pattern by controlling light transmittance using a halftone mask. Therefore, each of the photoresists PR4 may include a first portion PR4a and a second portion PR4b having different thicknesses. The first portion PR4a may be located in each of the portions overlapping the anode contact holes ACTH. In addition, the first portion PR4a may be located at edges of each photoresist PR4. The first portion PR4a may have a smaller thickness than the second portion PR4b.

The second portion PR4b may be located between the first portion PR4a overlapping each anode contact hole ACTH and the first portion PR4a located at the edges of each photoresist PR4. The second portion PR4b may have a greater thickness than the first portion PR4a.

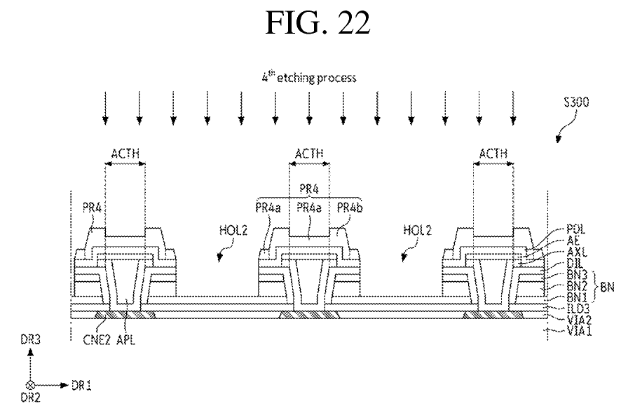

First, a dry etching process is performed using the photoresists PR4 as a mask. In current process, the pixel defining layer PDL, the element insulating layer DIL, the second bank layer BN2, and the third bank layer BN3 not overlapped by the photoresists PR4 may all be removed at once to form holes HOL2 as illustrated in FIG. 22.

In current process, side surfaces of the pixel defining layer PDL, side surfaces of the element insulating layer DIL, side surfaces of the second bank layer BN2, and side surfaces of the third bank layer BN3 which face the holes HOL2 may be located on the same line. In current process, the first bank layer BN1 overlapping the holes HOL2 may be exposed.

Next, a wet etching process is performed. In the current process, the second bank layer BN2 and the third bank layer BN3 including different metal materials may have different etch selectivities. Specifically, the third bank layer BN3 may have higher etch resistance than the second bank layer BN2 in the same etching process. In other words, the second bank layer BN2 may include a material having a higher etch rate than that of the third bank layer BN3 in the same etching process.

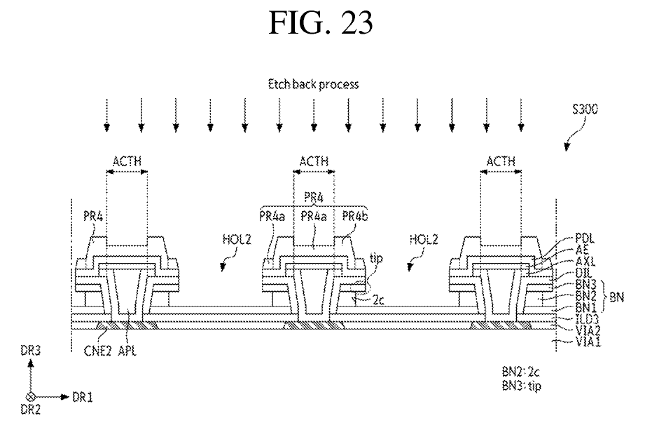

As illustrated in FIG. 23, through the current process, the third bank layer BN3 may include tips protruding more than (further than) side surfaces 2c of the second bank layer BN2 toward the holes HOL2. In the current process, the element insulating layer DIL and the pixel defining layer PDL may overlap the tips of the third bank layer BN3 in the third direction DR3. Redundant descriptions are omitted.

Next, an etch back process is performed. For example, the etch back process may be performed as a dry etch back process. In the current process, the first portions PR4a of the photoresists PR4 can be precisely etched using plasma or a RIE process.

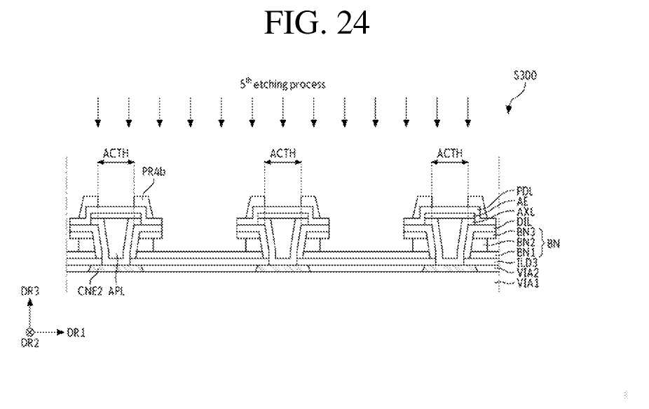

Through the current process, as illustrated in FIG. 24, the first portions PR4a of the photoresists PR4 may be removed, and the second portions PR4b of the photoresists PR4 may remain. Through the current process, a thickness of the second portion PR4b of each photoresist PR4 may be reduced by a thickness of the first portion PR4a.

Next, a fifth etching process is performed using the remaining second portions PR4b of the photoresists PR4 as a mask. For example, the fifth etching process may be performed as a dry etching process.

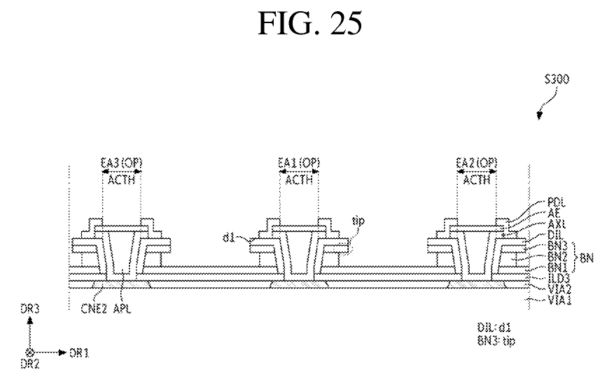

As illustrated in FIG. 25, through the current process, the pixel defining layer PDL not overlapped by the second portions PR4b of the photoresists PR4 may be removed to form emission openings OP in the portions overlapping the anode contact holes ACTH. The anodes AE may be exposed in portions overlapping the emission openings OP.

In addition, an edge portion of the pixel defining layer PDL which is not overlapped by the second portion PR4b of each photoresist PR4 may be removed. Accordingly, a portion of an upper surface d1 included in the element insulating layer DIL may be exposed.

As a result, the element insulating layer DIL and the pixel defining layer PDL included in the display device 10 of FIGS. 5 through 7 may form staircase-like steps. Redundant descriptions are omitted.

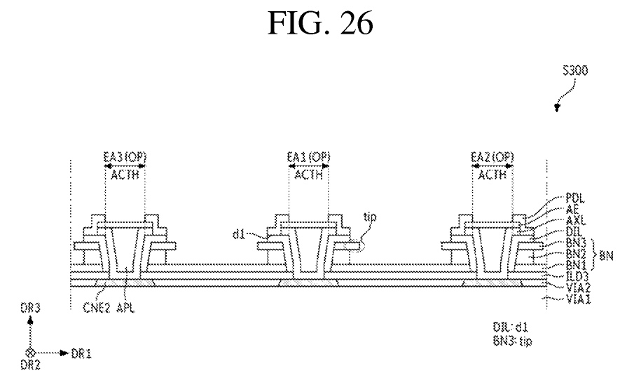

As illustrated in FIG. 26, in an embodiment, an edge portion of the element insulating layer DIL may be removed at the same time as the edge portion of the pixel defining layer PDL which is not overlapped by the second portion PR4b of each photoresist PR4. This may be achieved by controlling the process conditions (e.g., gas amount and process time) of the fifth etching process. Accordingly, the side surfaces of the pixel defining layer PDL and the side surfaces of the element insulating layer DIL may be located on the same line, and the tips of the third bank layer BN3 may be partially exposed.

As a result, the element insulating layer DIL and the third bank layer BN3 included in the display device 30 of FIGS. 9 through 11 may form staircase-like steps. Redundant descriptions are omitted.

Although not illustrated in the drawings, the photoresists PR4 may be removed through an ashing process.

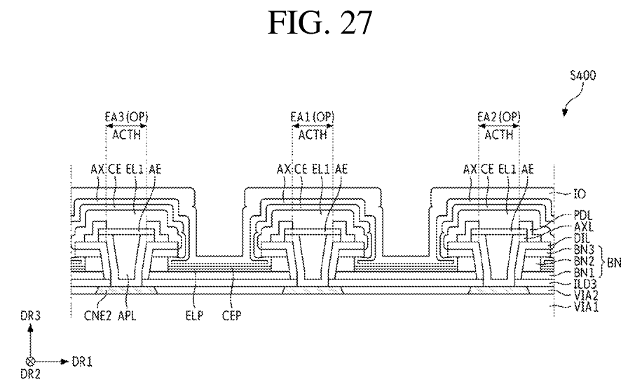

FIGS. 27 through 30 are cross-sectional views illustrating operation S400 of FIG. 12.

The forming of the light emitting layer, the cathode and the element inorganic layer on the anode (operation S400) will be described with reference to FIGS. 27 through 30.

Next, material layers for forming a first light emitting layer EL1, a cathode CE, and a cathode auxiliary electrode AX are deposited on each anode AE.

In the current process, a process of forming the first light emitting layer EL1 may be performed through a thermal deposition process. In the current process, a material that forms the first light emitting layer EL1 may be formed not only on the anode AE overlapping a first emission area EA1, but also on the anodes AE located in portions overlapping a second emission area EA2 and a third emission area EA3. The first light emitting layers EL1 located in the portions overlapping the first through third emission areas EA1 through EA3 may be spaced apart from each other.

In addition, the material that forms the first light emitting layers EL1 may also be formed on the first bank layer BN1. The material that forms the first light emitting layers EL1 located on the anodes AE and the material that forms the first light emitting layer EL1 located on the first bank layer BN1 may be spaced apart from each other. The material that forms the first light emitting layer EL1 located on the first bank layer BN1 may be temporarily referred to as an organic pattern ELP.

In the current process, a process of forming the cathode CE may be performed through a thermal deposition process or a sputtering process. The process of forming the cathode CE may have higher step coverage characteristics than the process of forming a first light emitting layer EL1. Therefore, the cathode CE may entirely cover the first light emitting layer EL1.

In the current process, a material that forms the cathode CE may be formed not only on the first light emitting layer EL1 overlapping the first emission area EA1, but also on the first light emitting layers EL1 located in the portions overlapping the second emission area EA2 and the third emission area EA3. The cathodes CE located in the portions overlapping the first through third emission areas EA1 through EA3 may be spaced apart from each other.

In addition, the material that forms the cathodes CE may be formed not only on the first light emitting layers EL1 but also on the organic pattern ELP. The material that forms the cathodes CE located on the first light emitting layers EL1 and the material that forms the cathode CE located on the organic pattern ELP may be spaced apart from each other. The material that forms the cathode CE formed on the first bank layer BN1 may be temporarily referred to as an electrode pattern CEP.

In the current process, the cathodes CE may contact the third bank layer BN3. Redundant descriptions are omitted.

A process of forming the cathode auxiliary electrode AX may be performed through a sputtering process. The process of forming the cathode auxiliary electrode AX may have higher step coverage characteristics than the process of forming the cathodes CE. Therefore, the cathode auxiliary electrode AX may be formed over the entire surface. In other words, a material layer for forming the cathode auxiliary electrode AX may entirely cover the cathodes CE and the electrode pattern CEP.

In the current process, a material that forms the cathode auxiliary electrode AX may contact the third bank layer BN3 and the second bank layer BN2. Redundant descriptions are omitted.

Next, a material layer for forming an element inorganic layer IO is formed on the cathode auxiliary electrode AX. The element inorganic layer IO may cover a structure under the element inorganic layer IO with a uniform thickness along the profile of the structure and thus may cover the entire cathode auxiliary electrode AX.

In the current process, the element inorganic layer IO may be formed through a layer forming process (e.g., a deposition process) for forming at least one of the inorganic materials described above.

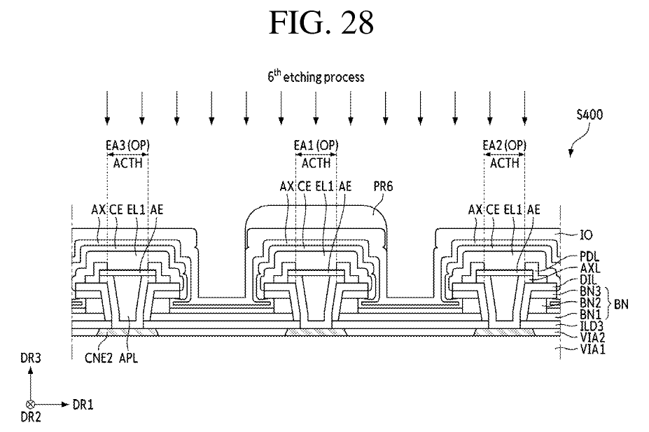

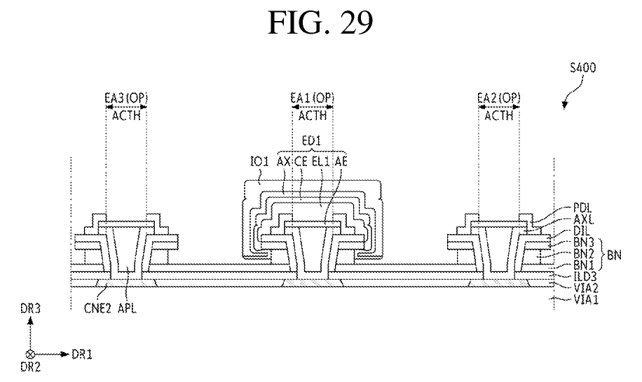

Next, as illustrated in FIGS. 28 and 29, a photoresist PR6 is formed in a portion overlapping the first emission area EA1 and a portion around the first emission area EA1, and a sixth etching process is performed using the photoresist PR6 as a mask.

In the current process, the material that forms the first light emitting layers EL1, the material that forms the cathodes CE, the material that forms the cathode auxiliary electrode AX, and a material that forms the element inorganic layer IO which are not overlapped by the photoresist PR6 may all be removed at once. Accordingly, the anode AE overlapping the second emission area EA2 and the anode AE overlapping the third emission area EA3 may be exposed again, and the element inorganic layer IO may be formed into a first element inorganic layer IO1.

As a result, a first light emitting element ED1 and the first element inorganic layer IO1 located in the portion overlapping the first emission area EA1 may be formed.

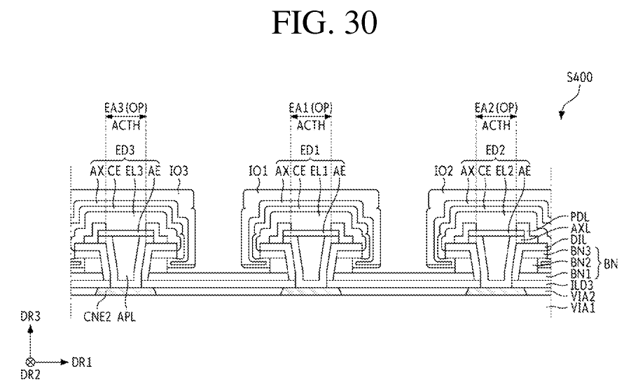

Next, a second light emitting layer EL2, a cathode CE, a cathode auxiliary electrode AX, and an element inorganic layer IO are formed on the anode AE overlapping the second emission area EA2 by repeating the above-described process. Through the current process, a second light emitting element ED2 and a second element inorganic layer IO2 overlapping the second emission area EA2 may be formed (refer to FIG. 30).

In addition, a third light emitting layer EL3, a cathode CE, a cathode auxiliary electrode AX, and an element inorganic layer IO are formed on the anode AE overlapping the third emission area EA3 by repeating the above-described process again. Through the current process, a third light emitting element ED3 and a third element inorganic layer IO3 overlapping the third emission area EA3 may be formed (refer to FIG. 30).

As a result, the display element layer EML illustrated in FIG. 5 may be formed. Redundant descriptions are omitted.

To recapitulate with reference to FIGS. 1 through 30, in the display device 10 or 30 of an embodiment, since the third bank layer BN3 includes tips, the light emitting layers EL and the cathodes CE spaced apart from adjacent light emitting layers EL and cathodes CE, respectively, can be formed in the portions overlapping the first through third emission areas EA1 through EA3 by a photolithography process without using a separate fine metal mask. Accordingly, the display device 10 or 30 of the embodiment can be easily fabricated.

In addition, the display device 10 or 30 of the embodiment includes the anode planarization layer APL, which fills the anode contact holes ACTH, in the portions overlapping the anode contact holes ACTH. Therefore, the anodes AE may be formed to have a relatively flat surface. Accordingly, the display device 10 of the embodiment can solve a contact defect of the anodes AE.

In addition, in the display device 10 of the embodiment, the pixel defining layer PDL and the element insulating layer DIL are formed to include staircase-like steps. Therefore, each of the cathodes CE may be formed to include a plurality of steps in a portion overlapping a non-emission area NLA, where the stepped shape of the cathodes CE corresponds to that of the pixel defining layer PDL and the element insulating layer DIL. Accordingly, the display device 10 of the embodiment can solve a short circuit defect of the cathodes CE.

In addition, in the display device 30 of the embodiment, the third bank layer BN3 and the element insulating layer DIL are formed to include staircase-like steps. Therefore, each of the cathodes CE may be formed to include a plurality of steps in the portion overlapping the non-emission area NLA, where the stepped shape of the cathodes CE corresponds to that of the third bank layer BN3 and the element insulating layer DIL. Accordingly, the display device 30 of the embodiment can solve a short circuit defect of the cathodes CE.

In addition, since the photoresists PR4 are formed using a halftone mask in the process of fabricating the display device 10 or 30 of the embodiment, multiple etching processes (e.g., the fourth etching process and the fourth etching process) can be performed using the same photoresists PR4. Therefore, the display device 10 or 30 of the embodiment can reduce the fabrication cost and the number of fabrication processes.

In an embodiment, a method of providing a display device includes providing an anode contact hole which penetrates a bank structure and an element insulating layer which is on the bank structure, providing an anode auxiliary electrode and an anode planarization layer in the anode contact hole, providing an anode of a light emitting element on the anode auxiliary electrode and the anode planarization layer, the anode planarization layer being between the anode auxiliary electrode and the anode, providing a pixel defining layer on the anode, providing a tip of the bank structure and an emission opening in the pixel defining layer, after the providing of the pixel defining layer on the anode, and providing a light emitting layer of the light emitting element, a cathode of the light emitting element and an element inorganic layer, on the anode.

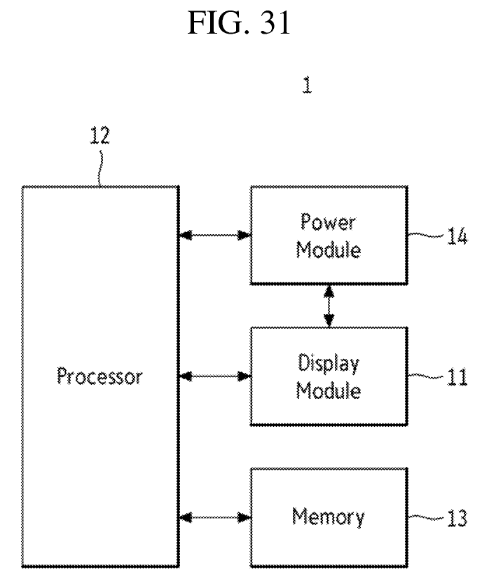

FIG. 31 is a block diagram of an electronic device 1 according to an embodiment.

Referring to FIG. 31 in addition to FIGS. 1 through 30, the display devices 10 and 30 according to the embodiments can be applied to various electronic devices 1. An electronic device 1 according to an embodiment includes the above-described display device 10 or 30 and may further include modules or devices having other additional functions, in addition to the display device 10 or 30.

The electronic device 1 according to the embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module. The power conversion module may generate power necessary for the operation of the electronic device 1 by converting power supplied by the power supply module.

At least one of the elements of the electronic device 1 described above may be included in a display device according to the above-described embodiments. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 1.

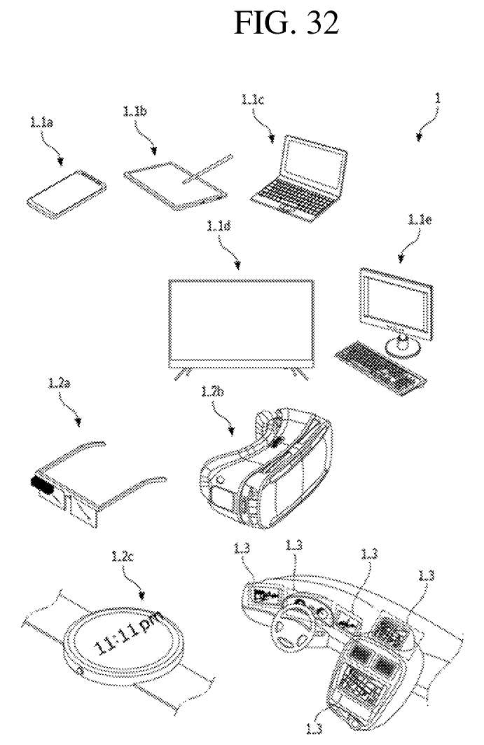

FIG. 32 is a schematic diagram of electronic devices according to various embodiments.

Referring to FIG. 32,various electronic devices 1 to which the display devices 10 and 30 according to the embodiments are applied may include image display electronic devices such as a smartphone 1_1a, a tablet personal computer (PC) 1_1b, a laptop 1_1c, a television 1_1d, and a desk monitor 1_1e. In addition, the various electronic devices 1 to which the display devices 10 and 30 according to the embodiments are applied may include wearable electronic devices including a display module, such as smart glasses 1_2a, a head-mounted display 1_2b and a smart watch 1_2c, and vehicle electronic devices 1_3 including a display module, such as a center information display (CID) and a room mirror display placed on an instrument cluster, center fascia and dashboard of a vehicle.

In an embodiment, an electronic device includes a display device,; and a display module, a processor, a memory or a power module connected to the display device. The display device includes a substrate including an emission area and a non-emission area, a bank structure on the substrate, the bank structure including a tip which faces the non-emission area, an anode contact hole penetrating the bank structure, the anode contact hole overlapping the emission area, a light emitting element on the bank structure, the light emitting element including an anode, a light emitting layer and a cathode overlapping the anode contact hole, an element insulating layer between the bank structure and the anode, and a pixel defining layer on the element insulating layer, covering an edge of the anode, and defining an emission opening overlapping the anode contact hole. A side surface of the pixel defining layer and a side surface of the tip of the bank structure face the non-emission area, and the side surface of the pixel defining layer is spaced apart from the side surface of the tip of the bank structure in a direction toward the anode contact hole.

The display device may further include an anode auxiliary electrode in the anode contact hole and between the anode and the element insulating layer, and an anode planarization layer in the anode contact hole and between the anode and the anode auxiliary electrode. The anode auxiliary electrode covers the inner side surface of the first bank layer, the inner side surface of the second bank layer and the inner side surface of the third bank layer which face the anode contact hole, and the anode planarization layer is entirely surrounded by the anode and the anode auxiliary electrode.

The bank structure may include a first bank layer, a second bank layer on the first bank layer, a third bank layer on the second bank layer, each of the first bank layer, the second bank layer and the third bank layer including an outer side surface facing the non-emission area and an inner side surface facing the anode contact hole, and the third bank layer protruding further than the side surface of the second bank layer, toward the non-emission area, to define the tip of the bank structure. The element insulating layer covers an upper surface of the third bank layer and extends into the contact hole along each of the inner side surface of the first bank layer, the inner side surface of the second bank layer and the inner side surface of the third bank layer which face the anode contact hole.

In the non-emission area the ,side surface of the pixel defining layer and a side surface of the element insulating layer which face the non-emission area form a step, and the light emitting layer and the cathode include a stepped structure corresponding to the step.

In the non-emission area, the outer side surface of the third bank layer and the side surface of the element insulating layer form a step, and the light emitting layer and the cathode include a stepped structure corresponding to the step.

Embodiments of the disclosure should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising an emission area and a non-emission area;
a bank structure on the substrate, the bank structure comprising a tip which faces the non-emission area;
an anode contact hole penetrating the bank structure, the anode contact hole overlapping the emission area;
a light emitting element on the bank structure, the light emitting element comprising an anode, a light emitting layer and a cathode overlapping the anode contact hole;
an element insulating layer between the bank structure and the anode; and
a pixel defining layer on the element insulating layer, covering an edge of the anode, and defining an emission opening overlapping the anode contact hole,
wherein
a side surface of the pixel defining layer and a side surface of the tip of the bank structure face the non-emission area, and
the side surface of the pixel defining layer is spaced apart from the side surface of the tip of the bank structure in a direction toward the anode contact hole.

2. The display device of claim 1,
wherein the bank structure comprises:
a first bank layer;
a second bank layer on the first bank layer;
a third bank layer on the second bank layer;
each of the first bank layer, the second bank layer and the third bank layer including an outer side surface facing the non-emission area and an inner side surface facing the anode contact hole; and
the third bank layer protruding further than the outer side surface of the second bank layer, toward the non-emission area, to define the tip of the bank structure, and
wherein the element insulating layer covers an upper surface of the third bank layer and extends into the anode contact hole along each of the inner side surface of the first bank layer, the inner side surface of the second bank layer and the inner side surface of the third bank layer which face the anode contact hole.

3. The display device of claim 2, further comprising:
an anode auxiliary electrode in the anode contact hole and between the anode and the element insulating layer; and
an anode planarization layer in the anode contact hole and between the anode and the anode auxiliary electrode,
wherein
the anode auxiliary electrode covers the inner side surface of the first bank layer, the inner side surface of the second bank layer and the inner side surface of the third bank layer which face the anode contact hole, and
the anode planarization layer is entirely surrounded by the anode and the anode auxiliary electrode.

4. The display device of claim 3, wherein an upper surface of the element insulating layer comprises:
a first portion in contact with the anode auxiliary electrode; and
a second portion in contact with the pixel defining layer.

5. The display device of claim 4, wherein the upper surface of the element insulating layer further comprises:
a third portion in contact with the light emitting layer, and
the second portion between the first portion and the third portion.

6. The display device of claim 2, wherein in the non-emission area:
the side surface of the pixel defining layer and a side surface of the element insulating layer which face the non-emission area form a step, and
the light emitting layer and the cathode comprise a stepped structure corresponding to the step.

7. The display device of claim 6, wherein the side surface of the element insulating layer is coplanar with the side surface of the tip.

8. The display device of claim 2, wherein a side surface of the element insulating layer faces the non-emission area and is spaced apart from the side surface of the tip in the direction toward the anode contact hole.

9. The display device of claim 8, wherein the side surface of the pixel defining layer and the side surface of the element insulating layer which face the non-emission area are coplanar.

10. The display device of claim 9, wherein the outer side surface of the third bank layer and the side surface of the element insulating layer form a step, and
the light emitting layer and the cathode comprise a stepped structure corresponding to the step.

11. The display device of claim 9, wherein the upper surface of the third bank layer comprises a first portion in contact with the element insulating layer and a second portion in contact with the light emitting layer.

12. The display device of claim 2, further comprising:
a cathode auxiliary electrode on the cathode; and
an element inorganic layer on the cathode auxiliary electrode,
wherein
the cathode contacts the tip which is defined by the third bank layer,
the cathode auxiliary electrode contacts the second bank layer, and
the element inorganic layer is spaced apart from the first bank layer in a direction perpendicular to a surface of the substrate.

13. A method of providing a display device, the method comprising:
providing an anode contact hole which penetrates a bank structure and an element insulating layer which is on the bank structure;
providing an anode auxiliary electrode and an anode planarization layer in the anode contact hole;
providing an anode of a light emitting element on the anode auxiliary electrode and the anode planarization layer, the anode planarization layer being between the anode auxiliary electrode and the anode;
providing a pixel defining layer on the anode;
providing a tip of the bank structure and an emission opening in the pixel defining layer, after the providing of the pixel defining layer on the anode; and
providing a light emitting layer of the light emitting element, a cathode of the light emitting element and an element inorganic layer, on the anode.

14. The method of claim 13, wherein in the providing of the tip of the bank structure and the emission opening after the providing of the pixel defining layer on the anode, the pixel defining layer is provided using a photoresist which comprises a first portion and a second portion having different thicknesses, and the first portion and the second portion of the photoresist are formed using a halftone mask.

15. The method of claim 14, wherein in the providing of the light emitting layer, the cathode and the element inorganic layer on the anode, the light emitting layer and the cathode are formed by a photolithography process.

16. An electronic device comprising:
a display device; and
a display module, a processor, a memory or a power module connected to the display device,
wherein the display device comprises:
a substrate comprising an emission area and a non-emission area;
a bank structure on the substrate, the bank structure comprising a tip which faces the non-emission area;
an anode contact hole penetrating the bank structure, the anode contact hole overlapping the emission area;
a light emitting element on the bank structure, the light emitting element comprising an anode, a light emitting layer and a cathode overlapping the anode contact hole;
an element insulating layer between the bank structure and the anode; and
a pixel defining layer on the element insulating layer, covering an edge of the anode, and defining an emission opening overlapping the anode contact hole,
wherein
a side surface of the pixel defining layer and a side surface of the tip of the bank structure face the non-emission area, and
the side surface of the pixel defining layer is spaced apart from the side surface of the tip of the bank structure in a direction toward the anode contact hole.

17. The electronic device of claim 16,
wherein the bank structure comprises:
a first bank layer;
a second bank layer on the first bank layer;
a third bank layer on the second bank layer;
each of the first bank layer, the second bank layer and the third bank layer including an outer side surface facing the non-emission area and an inner side surface facing the anode contact hole; and
the third bank layer protruding further than the side surface of the second bank layer, toward the non-emission area, to define the tip of the bank structure,
wherein the element insulating layer covers an upper surface of the third bank layer and extends into the contact hole along each of the inner side surface of the first bank layer, the inner side surface of the second bank layer and the inner side surface of the third bank layer which face the anode contact hole.

18. The electronic device of claim 17, further comprising:
an anode auxiliary electrode in the anode contact hole and between the anode and the element insulating layer; and
an anode planarization layer in the anode contact hole and between the anode and the anode auxiliary electrode,
wherein
the anode auxiliary electrode covers the inner side surface of the first bank layer, the inner side surface of the second bank layer and the inner side surface of the third bank layer which face the anode contact hole, and
the anode planarization layer is entirely surrounded by the anode and the anode auxiliary electrode.

19. The electronic device of claim 18, wherein an upper surface of the element insulating layer comprises:
a first portion in contact with the anode auxiliary electrode;
a second portion in contact with the pixel defining layer; and
a third portion in contact with the light emitting layer,
wherein the second portion is between the first portion and the third portion.

20. The electronic device of claim 19, wherein in the non-emission area:
the side surface of the pixel defining layer and a side surface of the element insulating layer which face the non-emission area form a step, and
the light emitting layer and the cathode comprise a stepped structure corresponding to the step.
